(19) United States
(12) Patent Application Publication
(10) Pub. No.: US 2002/0144895 A1
(43) Pub. Date: Oct. 10, 2002

(54) Methods and systems for enhanced fluid delivery of electrical currents to fluidic systems

(75) Inventors: Seth R. Stern, Mountain View, CA (US); J. Wallace Parce, Palo Alto, CA (US); Carlton Brooks, Menlo Park, CA (US)

Correspondence Address: CALIPER TECHNOLOGIES CORP, 605 FAIRCHILD DRIVE, MOUNTAIN VIEW, CA, 94043, US

(73) Assignee: Caliper Technologies Corp., Mountain View, CA

(21) Appl. No.: 10/076,135

(22) Filed: Feb. 14, 2002

Related U.S. Application Data
(60) Provisional application No. 60/269,239, filed on Feb. 15, 2001.
(60) Provisional application No. 60/269,245, filed on Feb. 15, 2001.
(60) Provisional application No. 60/334,315, filed on Nov. 30, 2001.

(51) Int. Cl. C25C 7/00; C30B 7/12; C25B 9/00; B01J 2/00

(52) U.S. Cl. 204/242; 205/687

(57) ABSTRACT

Microfluidic devices, systems and methods that are operated and/or configured to enhance the passage of electrical current from power supplies to the fluids within the system. The devices, methods and systems utilize alternate electrode and system configurations to permit transfer of current at lower voltages, minimize water hydrolysis at the electrode/fluid interface and/or permit accurate in situ measurement of the parameters of processes carried out in those devices and systems.

### CROSS-REFERENCE TO RELATED APPLICATION

This application is related to U.S. Provisional Patent Application Nos. 60/269,245 and 60/269,239, each filed Feb. 15, 2001, and 60/334,315, filed Nov. 30, 2001, each of which is incorporated herein by reference in it's entirety for all purposes.

### COPYRIGHT NOTIFICATION

Pursuant to 37 C.F.R. § 1.71(e), Applicants note that a portion of this disclosure contains material which is subject to copyright protection. The copyright owner has no objection to the facsimile reproduction by anyone of the patent document or patent disclosure, as it appears in the Patent and Trademark Office patent file or records, but otherwise reserves all copyright rights whatsoever.

### BACKGROUND OF THE INVENTION

Microfluidic devices have dramatically improved the performance of many significant analytical and preparative processes relevant to diverse disciplines, including medical diagnostics, molecular biology, forensics, genomics, and molecular evolution. Many of these processes utilize applied electric fields to manipulate materials, e.g., through direction, separation, or control of environmental conditions. By way of example, early descriptions of microfluidic devices and systems utilized electric fields to move materials through channels of these devices through either electrophoresis or electroosmosis. Such movement was generally controlled by interfacing electrodes either with the channels themselves, where the electrodes are fabricated into the channels, or indirectly, through reservoirs disposed at the channel termini, where electrodes are simply immersed in fluids within those reservoirs.

Electrical current has also been described for use in controlling other parameters within microfluidic devices, including, e.g., temperature, during the performance of other useful processes. These processes utilize resistive or joule heating of fluidic materials within microfluidic devices by flowing current through an electrode or other conductive component positioned within or in electrical contact with fluid in a microchannel or other device cavity. The resulting flow of current into fluid within the cavities of a device heats the fluid by dissipating energy through the electrical resistance of the fluid.

Clearly the application of electrical currents to fluidic, and particularly, microfluidic systems has important implications as an element of microfluidic technology. Despite its importance, however, that application of current can include a number of potential trouble areas. For example, application of electrical currents to fluids can lead to water electrolysis. The resulting gas formation, as well as local chemical environments caused by electrolysis can cause problems that potentially bias assay results, limit throughput or lead to device failure. In brief, water electrolysis involves the electrochemical decomposition of water due to oxidation/reduction reactions at electrode/electrolyte interfaces. For example, when electrons ejected from an electrode reduce hydrogen ions in solution, hydrogen atoms are formed at the electrode surface, where they combine among themselves or with other hydrogen ions and electrons to give gaseous hydrogen molecules. Similarly, hydroxyl ions in solution may be oxidized by donating electrons to an electrode, which ultimately leads to the formation of gaseous oxygen. Other gases may also be formed via redox reactions, such as chlorine gas, depending upon the nature of the electrolyte present at electrode surfaces.

Gas bubbles formed in microfluidic channels can pose substantial problems from both mechanical and electrical standpoints. From a mechanical standpoint, bubbles in microscale channels can form relatively impermeable plugs within channel systems that render such systems partially or completely inoperative. From an electrical standpoint, bubbles within channels result in channels having much higher resistances, which in turn, leads to greater, uncontrolled Joule heating, which in turn leads to increased chance of bubble formation. This runaway cascade again can lead to the inoperability of the overall system.

Application of electric fields through microfluidic channels has a number of other hurdles that can result in problems, including the need to apply relatively high voltages in order to get adequate current through those channels with high resistances. In particular, for longer channels with microscale dimensions, electrical resistances can be substantial. Where electrical currents are applied at terminal electrodes, high voltages may be required to deliver effective currents through the channels to accomplish whatever process is desired.

It would generally be desirable to be able to more effectively deliver electrical current to microfluidic systems with some, if not all of the aforementioned disadvantages and further to be able to monitor and control parameters effected by and effecting that delivery. The present invention is generally directed to meeting these and a variety of other needs.

### SUMMARY OF THE INVENTION

The present invention is generally directed to methods, systems, electrode and system configurations for more effectively applying electric fields to microfluidic channel systems for controlling the operation of those systems, e.g., fluid or other material movement, temperature monitoring and control, etc., with reduced negative effects as a result of applying those currents through the channel systems.

In at least one aspect, the invention provides methods for applying an electrical current through a fluid containing cavity that include the provision of the fluid containing cavity and contacting contacting at least first and second electrodes with the fluid in the fluid containing cavity, the first electrode having a relevant surface area in contact with the fluid in the fluid containing cavity and the second electrode having a second relevant surface area in contact with the fluid in the fluid containing cavity. An alternating current is applied to the fluid in the fluid containing cavity through the first and second electrodes at a first frequency. The first frequency and the relevant surface area are selected to avoid generation of gas bubbles at either of the first and second electrodes.

In a related aspect, the invention provides a method for applying electrical current through a fluid filled cavity where at least first and second electrodes with the fluid in the fluid containing cavity, the first electrode having a first relevant surface area in contact with the fluid at a first electrode/fluid interface, and the second electrode having a second relevant surface area that is in contact with the fluid at a second electrode/fluid interface. An alternating current is again applied to the fluid in the fluid containing cavity through the first and second electrodes, at a first frequency. The first frequency and the relevant surface area are selected to provide less than 1V of voltage drop across at least one of the first and second electrode/fluid interfaces.

In another aspect of the invention, methods are provided for applying current through a fluid containing cavity that comprise placing first, second and third electrodes in electrical contact with a fluid in the fluid containing cavity at first, second and third different points, respectively, the second point being disposed between the first point and the third point. A first current is applied between the first electrode and the second electrode simultaneously with the application of a second current between the second electrode and the third electrode.

The present invention also provides systems for carrying out the above-described methods. For example, in at least one aspect, the invention provides a system for applying electrical current through a fluid. The system comprises a first fluid filled cavity having first and second electrodes disposed in electrical contact with a fluid in the fluid filled cavity, where the first and second electrodes each having a relevant surface area. The system also includes an alternating current source operably coupled to the first and second electrodes, which source is set to provide alternating current between the relevant surface areas of the first and second electrodes through the fluid at a first frequency that avoids generation of gas bubbles in the fluid at either of the first or second electrodes.

In another aspect, the systems of the invention include a first fluid filled cavity having first, second and third electrodes disposed in electrical contact with fluid in the fluid containing cavity at first, second and third locations along the first fluid filled cavity, respectively, where the second electrode is positioned at a location between the first and third electrodes. The system includes one or more current sources operably coupled to the first, second and third electrodes and set to simultaneously supply a first current between the first and second electrodes and a second current between the second and third electrodes.

### BRIEF DESCRIPTION OF THE DRAWING

FIG. 1 schematically depicts one embodiment of a microfluidic device that is configured to preferentially provide nonfaradaic current in a microchannel of the device.

FIG. 2 schematically illustrates a circuit that is electrically equivalent to the electrode/microchannel configuration of FIG. 1.

FIG. 3A schematically shows one embodiment of a nonfaradaic electrode geometry.

FIG. 3B schematically depicts a circuit that models a uniform RC transmission line that is electrically equivalent to the nonfaradaic electrode geometry depicted in FIG. 3A.

FIG. 4 schematically shows one embodiment of an electrode disposed in a wide region of a device cavity.

FIG. 5 schematically depicts an electrode configuration in a semicircular shape to optimize current transfer.

FIG. 6A-D schematically illustrates a microchannel system employing optimized electrodes, as well as a clamshell electrode configuration with increased surface area.

FIG. 7 schematically illustrates a microchannel system similar to that shown in FIG. 6, but wherein the electrodes are positioned in cavities that are not directly in the main channel, in order to control slug dispersion in microfluidic devices.

FIG. 8 schematically shows an interdigitated electrode configuration that permits longer microscale cavities to be heated without increasing a applied voltage gradient.

FIG. 9 schematically illustrates a diagram of a channel segment having a unit length of channel between two electrodes.

FIG. 10 schematically illustrates a similar channel configuration as illustrated in FIG. 9, but including two electrically paralleled channel sections.

FIG. 11 schematically illustrates a channel section that has two electrically paralleled microscale cavity subsections that include two grounded peripheral electrode pairs.

FIG. 12 schematically illustrates a channel section having four electrically paralleled cavity subsections in a fashion similar to that illustrated in FIG. 11.

FIG. 13 schematically illustrates an interdigitated electrode/channel configuration where the electrodes are separate from the path of desired material flow, in order to minimize slug dispersion.

FIG. 14A-14C schematically show a microfluidic device that includes a capillary element from various viewpoints.

FIG. 15 schematically illustrates an integrated system that includes the microfluidic device of FIGS. 14A-C.

FIGS. 16A-E provide line plots of uniform RC Spice model plots of voltage vs. electrode length for various alternating current frequencies.

FIG. 17 schematically illustrates a low impedence electrode configuration for applying electric current through fluids.

### DETAILED DISCUSSION OF THE INVENTION INTRODUCTION

The present invention generally provides improved methods of delivering electrical currents to fluidic systems, and preferably, microfluidic systems. Application of currents to such systems is particularly useful in controlling movement of materials within those systems, controlling environmental parameters within those systems, e.g., temperature, and monitoring/sensing conditions within those systems, e.g., electrochemical conditions such as conductivity and relatedly, temperature. The methods, systems and devices described herein operate to permit: 1) the application of higher currents to fluidic systems without the associated and potentially problematic gas generation that results from water electrolysis; 2) application of currents across longer, more resistive conduits without the need for or associated dangers of excessive applied voltages; and 3) integrated sensing methods for use in these electrically controlled systems.

I. Minimization of Water Electrolysis/Gas Formation

The problems of water electrolysis and gas formation typically result from one of two types of processes that occur at electrode/electrolyte interfaces. The first type, generally referred to as a faradaic process, leads to water electrolysis and gas formation due to actual charge transfers between an electrode and an electrolyte. Like any chemical reaction, faradaic charge transfers are inhibited by the existence of an activation energy barrier between oxidized and reduced states. The barrier is typically exceeded when the potential drop across the electrode/electrolyte interface is greater than about 1V. The second type, commonly referred to as a nonfaradaic or capacitive process or pathway, involves processes such as adsorption and desorption where no charges actually cross the electrode/electrolyte interface. Nonfaradaic pathways do not produce water electrolysis or gas formation. During nonfaradaic processes, although no charges cross the interface, external transient currents flow when the potential, electrode surface area, or electrolyte composition changes. The total current through an electrode/electrolyte interface is the sum of distinct contributions from the faradaic and nonfaradaic processes. Nonfaradaic currents flow to charge or discharge the interfacial region or electrical double layer between the electrode and the electrolyte. This action is analogous to that of a capacitor, although unlike a conventional capacitor, the capacitance is a function of the voltage across the electrical double layer. The impedence across the interface is directly dependent upon the surface area and the alternating current frequency. Thus, by controlling surface area and alternating current frequency, it is possible to shunt essentially all the alternating current carried across electrode/electrolyte interfaces through nonfaradaic pathways without the deleterious effects of water electrolysis or gas formation. Nonfaradaic and faradaic pathways, and related concepts are described further in, e.g., Bard and Faulkner, Electrochemical Methods: Fundamentals and Applications, 2^{nd} Ed., John Wiley & Sons, New York, 2000, Scully et al., (Edt), Electrochemical Impedance: Analysis and Interpretation, America Society for Testing (1993), and Skoog et al., Principles of Instrumental Analysis, 5^{th} Ed., Harcourt Brace & Co., Philadelphia (1998).

The present invention generally provides methods, devices, and systems that are configured to preferentially provide electrical current to fluidic systems via nonfaradaic pathways. More specifically, the invention includes shunting alternating current away from faradaic pathways at electrode/electrolyte interfaces in microscale cavities of microfluidic devices to nonfaradaic pathways. As used herein, “alternating current” or “AC” refers to any non-direct current that integrates over time to zero. Alternating currents are utilized, inter alia, in the devices of the invention to resistively heat fluidic materials within microscale cavities. Advantages of delivering current to microscale cavities via nonfaradaic pathways include minimizing water electrolysis and gas formation which otherwise occur as current crosses electrode/electrolyte interfaces through faradaic or redox pathways. The electrolysis of water and the formation of gas generally bias assay results or otherwise negatively impact microfluidic applications.

A “faradaic pathway,” “faradaic process,” “redox pathway,” or “redox process,” as used herein, refers to a pathway or process that conducts current across an electrode/electrolyte interface through a direct transfer of charge (e.g., electrons) via an oxidation or a reduction reaction. As also used herein, “current” refers to the movement of electric charges in a conductor, such as by electrons in an electronic conductor and by ions in an ionic conductor or electrolyte. Additionally, a “faradaic current,” as used herein, refers to the movement of electric charges due to oxidation or reduction reactions occurring at electrode/electrolyte interfaces. That is, faradaic currents result from faradaic pathways or processes. Furthermore, a “faradaic electrode,” as used herein, refers to an electrode portion of a system that is not configured to preferentially provide nonfaradaic current in microscale cavities of a microfluidic device.

In contrast, a “nonfaradaic pathway,” “nonfaradaic process,” “capacitive pathway,” or “capacitive process,” as used herein, refers to a pathway or process that conducts currents through electrode/electrolyte interfaces without accompanying oxidation or reduction reactions. Further, a “nonfaradaic current” or “capacitive current,” as used herein, refers to the electric charge movement that charges or discharges electrical double layers at electrode/electrolyte interfaces. Nonfaradaic currents do not involve chemical reactions; rather, only the accumulation (or removal) of electric charges on the electrode and in the electrolyte near the electrode. Nonfaradaic currents result from nonfaradaic pathways or processes. In addition, a “nonfaradaic electrode,” as used herein, refers to an electrode that is configured to preferentially provide nonfaradaic current in microscale cavities of a microfluidic device.

In a number of instances, dimensions are described in terms of the path of current flow. In such cases, these dimensions refer to the distance or dimension of the electrical path between two recited points or the electrical path through a given segment of fluid.

As noted previously, the present invention generally provides methods and related devices for passing current through fluid containing channels, and preferably, microscale fluid containing channels, while minimizing electrolysis of water and the consequent gas formation. The methods include shunting AC away from faradaic pathways at one or more electrodes (e.g., 1, 2, 3, 1 0 4, 5, 6, 7, 8, 9, 10 or more electrodes) at least partially disposed within a microscale cavity (e.g., a microchannel, a capillary channel, a microscale reservoir, or the like) of the microfluidic device to nonfaradaic pathways when the one or more electrodes are in contact with an electrolyte in the microscale cavity. As used herein, an “electrolyte” refers to a solution that includes at least one chemical compound (e.g., an acid, base, salt, or the like) that dissociates into electrically charged ions when dissolved in the solvent.

An electrode for use in a configured system of the invention typically includes a lower impedance to the nonfaradaic pathway relative to an impedance to the faradaic pathway, which effectively shunts current away from the faradaic pathway to the nonfaradaic pathway. The current shunt to the nonfaradaic pathway is generally effected by limiting a potential drop across an interface between the electrolyte and a given electrode to at most about 1V, thus minimizing electrolysis of water and gas formation in the microscale cavity. As described further below, the present invention also relates to various electrode geometries, which efficiently exploit these current shunts. As used herein, an “electrode geometry” refers to the shape or form of a surface area of an electrode portion exposed within a microfluidic device cavity.

Configuration of systems to maximize nonfaradaic currents typically involve one or more of varying the frequency of the applied alternating current and varying the relevant surface area of the electrodes through which the currents are applied. In particular, by increasing the frequency and/or the relevant surface area of the electrodes, one can pass increasing levels of current through a microfluidic passage with minimum faradaic component. In brief, the rapidity of the current's rise and fall time, when combined with a larger surface area through which the current passes is configured such that voltage drop across the electrode/fluid interface is maintained at less than 1V, the level at which gas formation generally occurs.

As will be apparent, in addition to electrode surface area and current frequency, the appropriate configuration of a system will depend upon electrolyte composition, and the amount of desired applied current, e.g., to achieve the desired heating or other result. Thus, a wide variety of different configurations are envisioned by the instant invention.

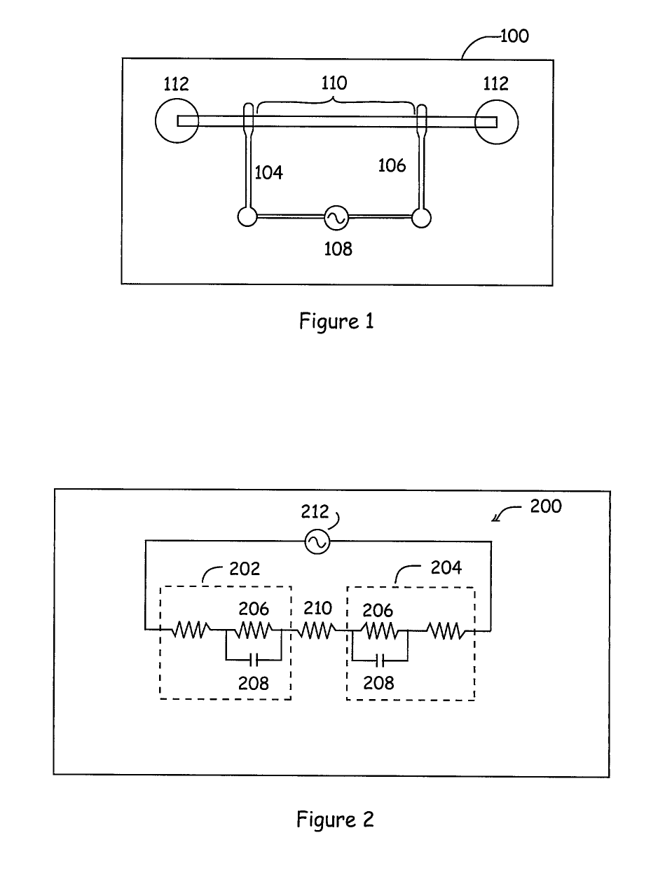

FIG. 1 schematically illustrates a simple example of a microfluidic device that includes electrical interfaces for applying electrical current through the channel of the device. As shown, the device includes body structure 100 having electrolyte-filled microchannel 102 fabricated therein, first and second electrodes (104 and 106, respectively) at least partially disposed within microchannel 102 (i.e., at least one surface of each electrode is in direct contact with the electrolyte solution), and electrically coupled to sinusoidal AC voltage source 108 as the electrical control system. An electrical control system of the invention typically applies a maximum voltage of between about 100 V_{RMS} and about 10000 V_{RMS}. In preferred systems, the electrical control system applies a maximum voltage of about 3000 V_{RMS} (e.g., about 8500 Vₚ₋ₚ), while for most applications described herein, applied voltages of less than 1000V are often used, depending upon the length of heated channel segment.

Additionally, for certain applications, e.g., heating, first and second electrodes (104 and 106) can be disposed between about 1 mm and about 100 mm, more typically between about 1 mm and about 50 mm, and usually about 20 mm apart from one another in microchannel 102. Section 110 of electrolyte-filled microchannel 102 disposed between first and second electrodes (104 and 106) models a simple channel resistance (R_{CH}). R_{CH} is characteristic of the bulk solution and independent of the electrode reaction. Bulk fluid resistance within the microscale cavities of the invention is typically between about 0.1 Megohm/mm and about 100 Megohm/mm of cavity length, more typically between about 0.1 Megohm/mm and about 10 Megohm/mm of cavity length, and usually about 1 Megohm/mm of cavity length. As additionally shown, wells 112 are also fabricated in body structure 100 and fluidly communicate with microchannel 102. Optionally, in certain cases, one or both of first and second electrodes (104 and 106) is disposed in one of wells 112. Sinusoidal AC voltage source 108 is configured to permit alternating current to flow between first and second electrodes (104 and 106) in microchannel 102.

In accordance with the present invention, the sinusoidal AC voltage source 108 and at least one of first and second electrodes (104 and 106) is configured to preferentially provide nonfaradaic current in microchannel 102. In particular, the AC current source is controlled to apply alternating current at a frequency across the relevant surface area of the electrode so as to maintain the voltage drop across the electrode/fluid interface at less than 1V. In preferentially providing non-faradaic current, the invention does not foreclose the possibility that some faradaic current is being passed. However, it is preferred that the amount of faradaic current in the microscale cavity generally is below a threshold level, e.g., the current level produces at most an amount of gas that is soluble in solution or is otherwise below a level that produces gas bubbles.

Typically, the alternating current flow between electrodes includes at least about 90 percent nonfaradaic current, more typically at least about 95 percent nonfaradaic current, and usually at least about 98 percent nonfaradaic current. In preferred embodiments, the alternating current flow resistively heats a segment of microchannel 102 at least between first and second electrodes (104 and 106) (e.g., to denature double-stranded DNAs and/or proteins in the segment). For example, the resistive heating typically increases electrolyte temperature in the segment of the microscale cavity by about 5° C. or more, or by about 30° C. or more.

As used herein, “electrode configuration” refers to a relative orientation or arrangement of electrodes within microfluidic device cavities. In addition, a “nonfaradaic electrode configuration,” as used herein, refers to an electrode configuration that includes at least one nonfaradaic electrode. Additional electrode configurations and geometries are described below.

FIG. 2 schematically shows a circuit that is electrically equivalent to the electrode/microchannel configuration depicted in FIG. 1. As shown, electrical circuit 200 includes two electrode impedances (Z_{EL}) 202 and 204, which correspond to first and second electrodes 104 and 106. Each electrode impedance includes a paralleled nonlinear resistor (R_{REDOX}) 206 and a double-layer capacitor (C_{DL}) 208 in series with simple channel resistance (R_{CH}) 210 and electrically connected to sinusoidal AC voltage source 212. R_{REDOX} 206 models faradaic electron transfer processes or pathways at the electrode/electrolyte interface, which typically lead to, e.g., oxygen and/or hydrogen gas evolution (i.e., water electrolysis) and bubble formation when the potential drop across the interface (i.e., the resistor) exceeds about 1V. In contrast, C_{DL} 208 models the electrode/electrolyte double-layer capacitor, which results from the accumulation of opposite charges at the electrode/electrolyte interface (e.g., electrons at the electrode surface neutralized by positive counter ions from the electrolyte). For example, an electrical double layer at an interface of an electrode and an electrolyte disposed within a microscale cavity of the devices of the invention typically includes a double layer capacitance of between about 1 μF/cm² and about 4000 μF/cm² or, e.g., about 20 μF/cm² or 0.2 pF/μm². Useful impedence ranges typically fall between about 1 KΩ and about 25 KΩ, and are often less than about 6.7 KΩ. Furthermore, the frequency of the alternating current is typically between about 1 KHz and about 100 KHz, and more typically is about 30 KHz.

The invention includes exploiting the low impedance of the C_{DL} to AC signals to effectively shunt current away from R_{REDOX}, thereby substantially reducing or eliminating water electrolysis and gas formation at device electrodes. To further illustrate, an electrode having a surface area exposed within a microscale cavity of about 8×10⁻⁴ cm² (e.g., 80 μm ×1000 μm) with a double layer capacitance of about 20 μF/cm² will have a total C_{DL} of about 0.016 μF. The ability of the C_{DL} to shunt current away from faradaic pathways, e.g., in the resistive heating applications of the invention, is estimated by the ratio of the capacitive reactance of the electrical double layer (X_{CDL}) and R_{CH}. For a maximum applied resistive heating voltage of about 3000 V_{RMS} (e.g., about 8000 Vₚ₋ₚ), this ratio should typically not exceed about 1/3000. If two electrodes, such as those depicted in FIG. 1, are disposed about 20 mm apart in a microscale cavity having a bulk fluid resistance of about 1 Megohm/mm of cavity length, then R_{CH} will be about 20 Megohm (MΩ). As such, X_{CDL} should not exceed about 6.7 KΩ (20 MΩ/3000). Furthermore, since the impedance of C_{DL} is a function of frequency as indicated by the expression as follows:

X_{CDL}=1/2πf C_{DL}

the frequency at which X_{CDL} is equal to 6.7 KΩ is calculated as about 1.5 KHz [i.e., 1/2π(6.7 KΩ)(0.016 μF)]. As a consequence, an electrical control system supplying AC at a frequency of at least about 1.5 KHz for this illustrative electrode configuration and geometry will not produce gas bubbles, even at full power and the resulting current may be utilized, e.g., to resistively heat the microscale cavity.

Essentially any electrode configured to preferentially deliver AC to microscale cavities via nonfaradaic pathways is optionally utilized in the devices of the present invention. As such, no attempt is made herein to describe all possible electrode geometries or configurations suitable for these purposes. Nonetheless, to further illustrate the invention, the following description is provided. At least a section of each electrode (e.g., a patterned metal layer) optionally includes a dimension (e.g., a thickness) of about 0.1 μm or less. Optionally, portions of electrodes exposed to fluidic materials in a microscale cavity include surface areas between about 1×10⁻⁶ cm² and about 100×10⁻⁴ cm². In preferred embodiments, these portions include surface areas of about 8×10⁻⁴ cm². See, e.g., the illustration of a nonfaradaic electrode having this surface area described above. A nonfaradaic electrode of the invention optionally includes a shape (e.g., a surface area exposed to fluidic materials within a microscale cavity) selected from, e.g., a regular n-sided polygon, an irregular n-sided polygon, a triangle, a square, a rectangle, a trapezoid, a circle, a semi-circle, an oval, or the like. In preferred embodiments, a nonfaradaic electrode includes a substantially uniform semi-circular shape, e.g., to uniformly distribute current in a microscale cavity. If devices include multiple nonfaradaic electrodes, any combination of these shapes is optionally utilized. The electrodes of the invention typically include at least an inner layer and at least an outer layer. The outer layer optionally includes, e.g., platinum disposed over the inner layer. Electrodes are optionally coated with a dielectric material. The inner layer generally includes a metal adhesion layer that includes, e.g., titanium, tungsten, an alloy thereof, or the like.

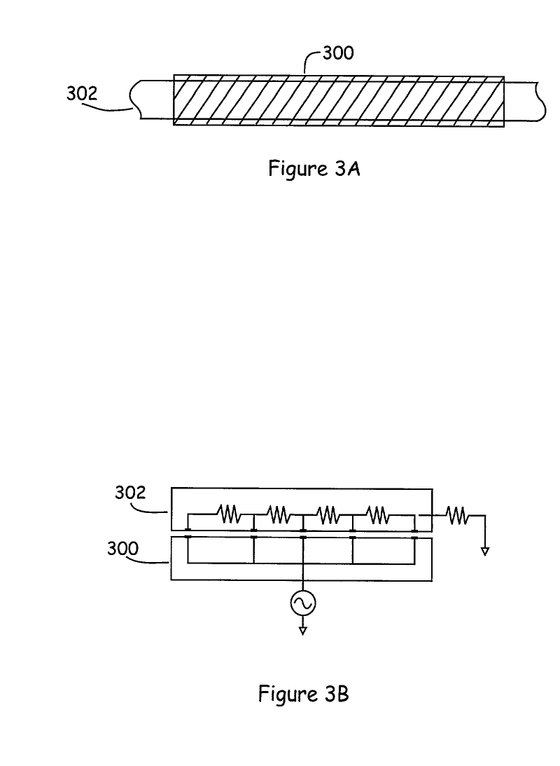

In accordance with the present invention, the controlled factor in electrode configuration is typically referred to as the relevant surface area of the electrode. Where current equally passes across the entire fluid contacting surface of the electrode, then the entire fluid contacting surface area of the electrode is the relevant surface area. However, in certain cases, electrodes are positioned within microfluidic channels or their interconnected reservoirs such that the majority of the current passes through only a portion or an edge of the electrode's overall surface. By way of example, when an electrode is patterned into a microscale cavity such that it is positioned parallel to the direction of current flow, only the leading edge of the electrode constitutes a relevant surface area of the electrode. This is a result of the resistance of the fluid being high in comparison to the resistance of the electrode itself, thereby causing the majority of the current to pass through the lowest resistance pathway, e.g., that furthest in the direction of current flow. This is schematically illustrated in FIGS. 3A and 3B. For purposes of illustration and clarity, the relevant surface area is generally used to describe the portion of the surface area of an electrode through which passes at least 90% of the total current passed through the electrode.

FIG. 3A schematically shows one embodiment of an electrode geometry in which an exposed surface area of rectangular electrode 300 extends over the entire surface width and a portion of the length of microchannel 302. FIG. 3B schematically depicts a circuit that models a uniform RC transmission line that is electrically equivalent to the electrode configuration depicted in FIG. 3B. As shown, the channel's resistance from the leading edge of the electrode is far less than that from the center or trailing edges of the electrode.

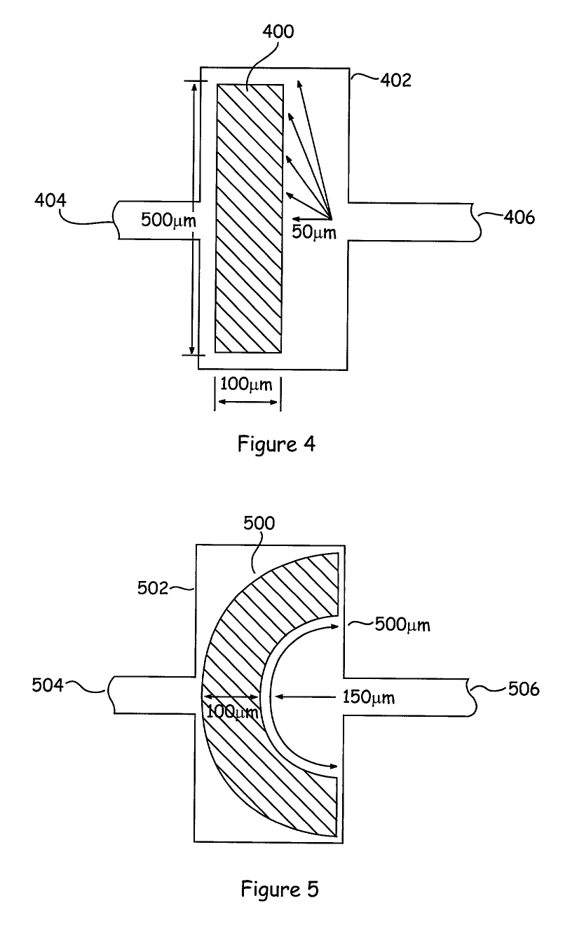

In order to increase surface area of electrodes to enhance nonfaradaic current, a number of different electrode configurations may be used. In microfluidic devices, for example, where the small size and compact nature of the overall device limits available space, an electrode's surface area is optionally increased by positioning a larger surfaced electrode in a wide region of the microscale cavity, e.g., as compared to other channels or cavities of the device which can accommodate the larger electrode. One illustration of this embodiment is schematically depicted in FIG. 4. As shown, the electrode 400 extends through at least a portion of wide region 402 of the device cavity in which the portion is wider than adjacent narrow regions 404 and 406 of the cavity. For exemplary purposes, various electrode and cavity dimensions are also represented.

As shown in FIG. 4, where the direction of current flow is parallel to the main plane of the electrode, e.g., in the direction of channel 406, it will be appreciated that the relevant surface area of electrode 400 is relatively small as compared to the overall fluid contacting surface of the electrode. In particular, because the current passes into channel 406, the resistance between electrode 400 and the opening of channel 406 is greater at the ends of the electrode and less near the center leading edge of the electrode. In such circumstances, the relevant surface area of the electrode can be increased by shaping the electrode to minimize differences in resistance across greater area of the electrode.

FIG. 5 schematically depicts an example of an electrode configuration that optimizes the relevant surface area of the electrode in accordance with the invention. As shown, semicircular electrode 500 extends through wide region 502 of the device cavity. As shown, adjacent narrow regions 504 and 506 typically intersect with wide region 502 proximal to a central region of substantially uniform semi-circular-shaped nonfaradaic electrode 500. FIG. 5 also includes certain exemplary dimensions. For example, a cross-sectional midpoint of the intersection of adjacent narrow region 506 and wide region 502 is generally about 150 μm from an edge of substantially uniform semi-circular-shaped nonfaradaic electrode 500, which electrode is typically between about 25 μm and about 200 μm in width in at least one cross-sectional dimension. This cross-sectional dimension is 100 μm in FIG. 5. Additionally, an inner semi-circular edge of substantially uniform semi-circular-shaped nonfaradaic electrode 500 generally includes a length of between about 700 μm and about 1500 μm. The inner semi-circular edge of the electrode depicted in FIG. 5 is represented as 500 μm. As can be seen, the leading, or inner edge of the electrode, assuming current flow toward channel 506, is substantially equidistant from the opening of channel 506. This results in the entire leading edge of electrode 500 operating as the relevant surface area of the electrode. By increasing the surface area, one can conversely operate at lower frequencies of applied AC, while still avoiding excessive faradaic current.

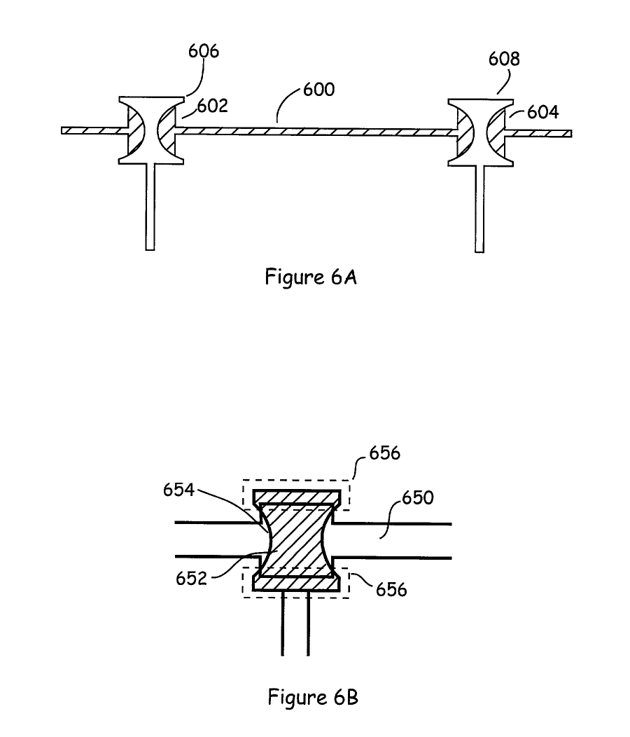

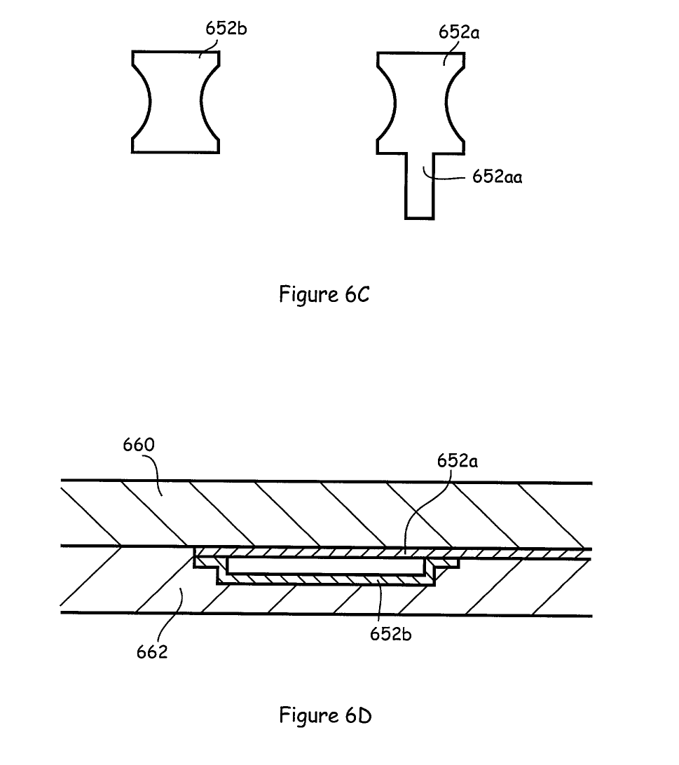

FIG. 6A schematically illustrates a microscale cavity employing electrodes configured to optimize for relevant surface area, and thus permitting simpler operation in accordance with the invention. As shown, microchannel 600 includes wide regions 602 and 604, which have nonfaradaic electrodes 606 and 608, respectively, partially disposed therein. Each electrode includes a substantially uniform double semi-circular-shape, e.g., to uniformly distribute current. This uniform distribution of current passage from the electrode to the fluid increases the relevant surface area of the electrodes and permits more facile operation within the parameters of the invention.

In some cases, a further increase in the relevant surface area of an electrode or collection of electrodes may be desirable, e.g., where higher applied currents are desired, or electrolyte composition warrants. However, the surface area of an electrode is, at least partly dictated by the size of the fluidic channel or chamber in which the electrode is disposed. In order to increase surface area in these circumstances, the present invention also provides for the use of clamshell electrodes, e.g., electrodes that are disposed on or adjacent to two or more surfaces of a channel or chamber, instead of just one surface, or increasing relevant electrode surface area by providing electrodes with an uneven or roughened surface. FIG. 6B schematically illustrates a channel segment 650 that includes a clamshell electrode 652 that includes approximately twice the relevant surface area as the electrode illustrated in FIG. 6A, by virtue of the electrode surface extending over the bottom and top surfaces of the electrode chamber 654. As shown, the shaded area of the electrode indicates the overlapping portions of the upper and lower portions of the overall electrode, while the contacting area of the two electrode portions is shown by the dashed boxes 656.

FIG. 6C illustrates the separate electrode portions of the overall clamshell electrode, including the upper electrode portion 652a (which is fabricated onto the surface of the flat substrate) which is illustrated as including an electrical lead portion 1202aa for connection to a power source, and the lower electrode portion 652b (which is fabricated into the etched, or otherwise prepared well, on one substrate). The use of the terms “upper” and “lower” is solely for ease of discussion and is not intended to provide any limitation or requirement of orientation.

FIG. 6D illustrates this electrode configuration from a side view where the upper portion of the 30 electrode 652a is fabricated onto a flat substrate 660 while the lower portion of the electrode 652b is fabricated onto the structured substrate 662. Although described in terms of being fabricated into a well and on a flat substrate, it will be appreciated that the electrode configuration in accordance with this aspect of the invention could be fabricated on multiple surfaces of a channel or a chamber that is fabricated by different methods. For example, where a chamber is produced by mating two complementary wells on two different substrates, then the electrodes will typically be fabricated into the wells in each substrate. Similarly, where a chamber or channel is fabricated by providing a spacing material between two flat substrates, to define the channel or chamber, then the electrodes could be fabricated onto the flat surfaces of the two main substrates, e.g., as opposed to or in addition to the spacer. Alternatively, an increased surface area clamshell electrode may be separately fabricated from the substrates making up the device, and simply mounted into a chamber or channel of the device. In all cases, the surface area of the electrode can be fabricated to be greater than the largest footprint of the chamber portion or channel segment in which it is disposed. By footprint is meant the area of a channel segment or chamber portion in two dimensions, e.g., length and width. By way of example, if a channel segment in which the electrode is disposed is 1 mm² then the effective electrode surface area of a clamshell electrode can be produced to exceed this by 10%, 20%, 50% and even up to 100%, or could be 1.1 mm², 1.2 mm², 1.5 mm² and up to 2 mm².

Fabrication of clamshell electrodes is generally carried out by the same methods used to fabricate the single surface electrodes, described herein, e.g., sputtering, chemical vapor deposition, thermal or E-beam evaporation, electroplating, etc., followed by photolithographic lift-off techniques or etching methods that are known in the art. In the case of the clamshell electrode, however, an electrode portion is fabricated onto a planar upper substrate, e.g., the lid, as well as being fabricated onto the etched or structured substrate, e.g., the chamber or well. The electrode portion patterned onto the chamber is typically provided with dimensions sufficient to extend beyond the edge of the well, so that it contacts the electrode portion fabricated onto the upper substrate, during the process of bonding the two substrate layers together. For illustration, FIG. 6D shows the second or lower electrode portion 652b extending across the bottom surface of the chamber 654 that is fabricated into the substrate 662, up the side walls and over the upper edge of the chamber, where it is in contact with the first or upper electrode portion 652a that is patterned on the upper substrate 660. This forms an electrode “pocket” that has substantially greater surface area than a single electrode patterned on the upper surface of the chamber, e.g., electrode portion 652a alone.

Alternatively or additionally, electrode surface area can be effectively increased by providing those electrodes with uneven or roughened surfaces. Typically, such roughened surface electrodes may be prepared by depositing electrodes onto roughened surfaces, e.g., roughened by wet chemical etching, abrading or other known surface texturing methods. Alternatively or additionally, photolithographic techniques or other known techniques may be used to etch a defined pattern into the surface of the electrode to increase the electrode's overall surface area in contact with the fluid. Alternatively or additionally, electrodes may be patterned onto the surface in a thicker layer that is porous or otherwise uneven to increase its surface area, e.g., using modified sputtering or deposition techniques that yield rougher surfaces than are conventionally desired.

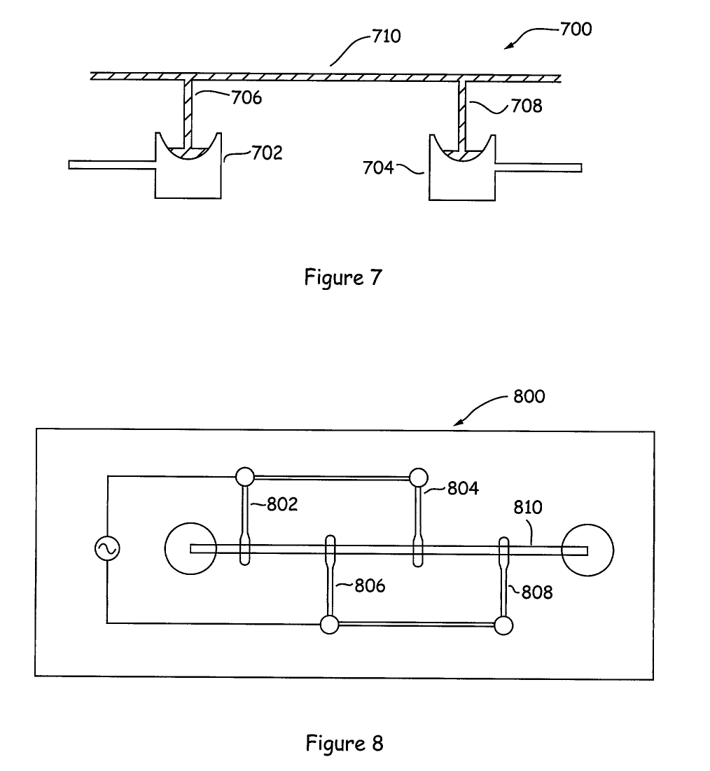

In optional aspects, it is often desirable to provide electrode contacts out of the stream of fluid or material flow in microfluidic devices. This provides benefits of making electrical contact with the system away from critical fluidic and chemical components. Additionally, for the electrode configurations described herein, the use of large, electrode containing cavities could provide a source of dispersion of fluid slugs if those larger cavities are positioned along the route of flow. Accordingly, in some embodiments, the wider electrode cavities are provided connected to the main cavity by way of side channels that fluidly and electrically connect the electrode chambers to the channel. An example of this type of structure is illustrated in FIG. 7. As shown, microscale cavity configuration 700 includes nonfaradaic electrodes 702 and 704 disposed in separate microscale cavities 706 and 708, respectively, which fluidly communicate with main microscale cavity 710 to minimize slug dispersion during fluid flow within main microscale cavity 710. For example, at least a portion of at least one separate microscale cavity is optionally wider than a cross-section of main microscale cavity 710. See, e.g., separate microscale cavities 706 and 708 in FIG. 7. As a result, the present invention optionally includes microfluidic devices configured to resistively heat cavity segments, while minimizing slug dispersion and diffusion to improve the throughput and performance of various microfluidic analytical and preparative processes.

II. Electrode Configurations for Optimizing Power Distribution and/or Minimizing Applied Voltages

As noted previously, there can be a number of issues associated with applying electrical currents through resistive fluidic channels. In particular, to achieve adequate current for a given operation, it may be necessary to apply extremely high voltages. Similarly, power distribution may vary across longer channels as a result of variations in current density through the various portions of the channel.

In order to alleviate these problems, the present invention also provides improved electrical interfacing with microscale fluidic channels by segmenting the relevant channel portions. Channel segmenting in the electrical context involves creating a number of circuits along a channel length in order to minimize the length, and thus resistance or variations in resistance across those circuits, as compared to a single circuit channel. In its simplest embodiment, segmenting simply requires placing at least three electrodes into electrical contact with different points of a channel through which a desired current is to be applied. However, in certain cases channels may be segmented into two, three, four, five, six, seven, eight or more different circuits, up to as many as one or two hundred different circuits, in order to divide the channel of interest into readily manageable circuits.

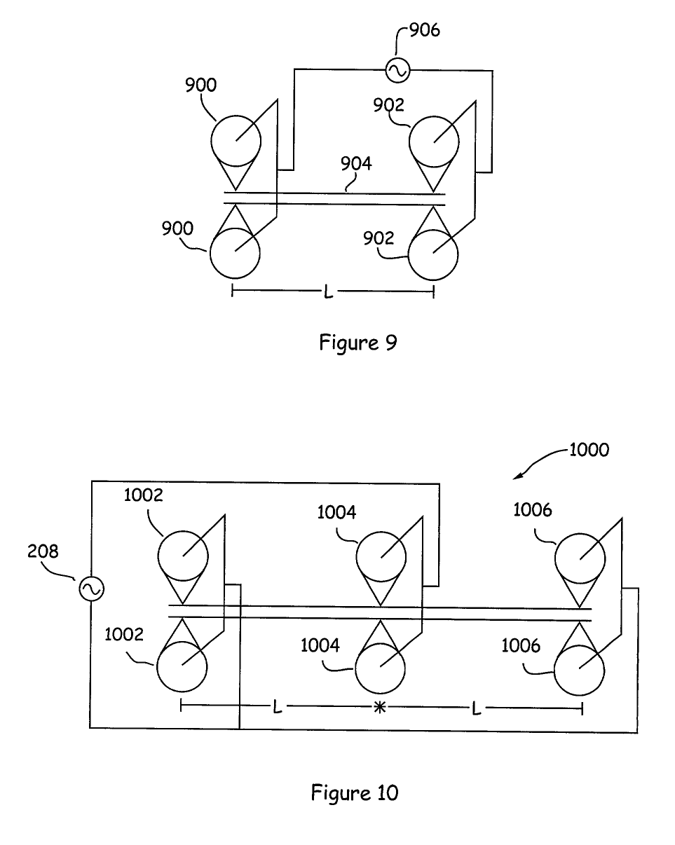

One problem, as noted above, associated with resistively heating microscale cavities of increasing length is a typical attendant increase in the applied voltage to maintain a given temperature over the increased cavity length. To illustrate, FIG. 9 schematically depicts a single microchannel unit length, L, disposed between electrodes 900 and 902, which are positioned proximal to microchannel 904. Electrodes 900 and 902 are electrically connected to sinusoidal AC voltage source 906. A mathematical expression that describes the relationship among power, applied voltage, and simple channel resistance between electrodes 900 and 902 (i.e., where the number of microchannel unit lengths, n, is 1) is as follows:

P₁=V₁²/R₁ (I)

where

P=power dissipated in fluid;

V=applied voltage; and

R=simple channel resistance between electrodes 900 and 902.

Simple channel resistance is characteristic of the bulk solution disposed within the microscale cavity, which in the invention is typically between about 0.1 Megohm/mm and about 100 Megohm/mm of cavity length, more typically between about 0.1 Megohm/mm and about 10 Megohm/mm of cavity length, and usually about 1 Megohm/mm of cavity length. Generally, applied voltages increase linearly with microscale cavity length in order to maintain constant power per unit microscale cavity length (e.g., per unit length, L). This is shown in equation (I), above, where power is directly proportional to the square of the applied voltage and inversely proportional to the electrical resistance of the fluid. So, if the microscale cavity length to be heated to a selected temperature were increased (i.e., if R were increased), the applied voltage would increase according to equation (I) to maintain the selected temperature over the increased length. To further illustrate, where n>1 (e.g., for heating more than one microchannel unit length, L), the following expression would apply:

P₂=V₂²/R₂ (II)

where

R₂=n*R₁; and

P₂=n*P₁.

Substituting into equation (II) leads to the following relationships:

P₂=n*P₁=n*V₁²/R₁=V₂²/R₂=V₂²/n*R₁; and thus to, (III)

n*V₁²/R₁=V₂²/n*R₁. (IV)

Solving for V₂² yields the following expression:

V₂²=n*V₁²/R₁*n*R₁=n²*V₁²; and ultimately to, (V)

V₂=n*V₁. (VI)

For example, if a microchannel unit length of 20 mm (i.e., L=20 mm) is heated with a maximum of about 3000 V_{RMS} (V₁), then an 80 mm cavity length (i.e., n=4) would utilize about 12000 V_{RMS} (i.e., n*V₁=4×3000 V_{RMS} ) for approximately equal performance. Such voltage increases, as noted above, are typically undesirable, inter alia, because excessively high voltages are dangerous and prone to arc-over, which may, e.g., damage the device and/or bias assay results.

The present invention solves this problem by electrically paralleling adjacent cavity segments, such that only drive currents increase (given by P=IV), rather than applied voltages, as cavity lengths increase. In particular, the invention provides to a microfluidic device electrically configured to maintain substantially constant power per subsection (e.g., a microchannel unit length, L) of a section of a microscale cavity (e.g., a microchannel, a capillary channel, a microscale reservoir, or the like) of the device. The device includes a body structure having the microscale cavity fabricated therein and at least three electrodes. At least a segment of each electrode is at least partially disposed within or proximal to the microscale cavity in the section. Electrodes are optionally uniformly or non-uniformly spaced within or proximal to the microscale cavity. The device also includes an electrical control system (e.g., a sinusoidal AC voltage source or the like) configured to permit alternating current to flow between selected electrodes in the microscale cavity such that microscale cavity subsections disposed between adjacent electrodes are electrically in parallel with one another to maintain substantially constant power per subsection of the section of the microscale cavity of the device. As used herein, “alternating current” or “AC” refers to any non-direct current that integrates over time to zero. The frequency of the alternating current is typically between about 1 KHz and about 100 KHz, preferably between 10 KHz and 50 KHz. During operation of the device, a voltage gradient remains substantially constant independent of a length of the section of the microscale cavity. For example, the electrical control system typically applies a maximum voltage across each subsection of the microscale cavity of between about 100 V_{RMS} and about 10000 V_{RMS}, (e.g., depending on the length of the particular subsection). To illustrate, for a subsection length of about 20 mm, the electrical control system typically applies at most about 3000 V_{RMS}. Furthermore, a sum of currents applied to the microscale cavity subsections is generally directly proportional to a length of the section of the microscale cavity.

In general, in accordance with this aspect of the invention, the electrodes are typically spaced apart by between 5 μm and 20 mm, in terms of the length of a current flow path, in order to achieve desired reductions in applied voltages or controllability of applied currents over the entire length of a channel. In many cases, the current path between electrodes is less than 10 mm, less than 5 mm and even less than 1 mm, e.g., from 5 μm to 1,5 or 10 mm apart along the path of current flow.

FIG. 10 schematically illustrates an embodiment of the invention that includes electrodes disposed proximal to a microscale cavity. As shown, device 1000 includes three electrode pairs 1002, 1004, and 1006, respectively, disposed proximal to two paralleled microchannel subsections, L. Relative to the single microchannel unit length, L, depicted in FIG. 1, to achieve an equivalent power in both subsections depicted in FIG. 2 (assuming L is the same in both figures) without doubling the applied voltage, the present invention doubles the drive current instead. Optionally, more than two paralleled subsections are included. As noted above, individual electrodes or as depicted in FIG. 2, electrode pairs, are optionally uniformly or non-uniformly spaced from one another along a given microscale cavity. Stated otherwise, microchannel unit or subsection lengths are optionally the same as or different from one another. For example, each microscale cavity subsection typically includes a length of between about 1 mm and about 100 mm, more typically includes a length of between about 1 mm and about 50 mm, and usually includes a length of about 20 mm. As further shown, each electrode pair is electrically connected to sinusoidal AC voltage source 1008.

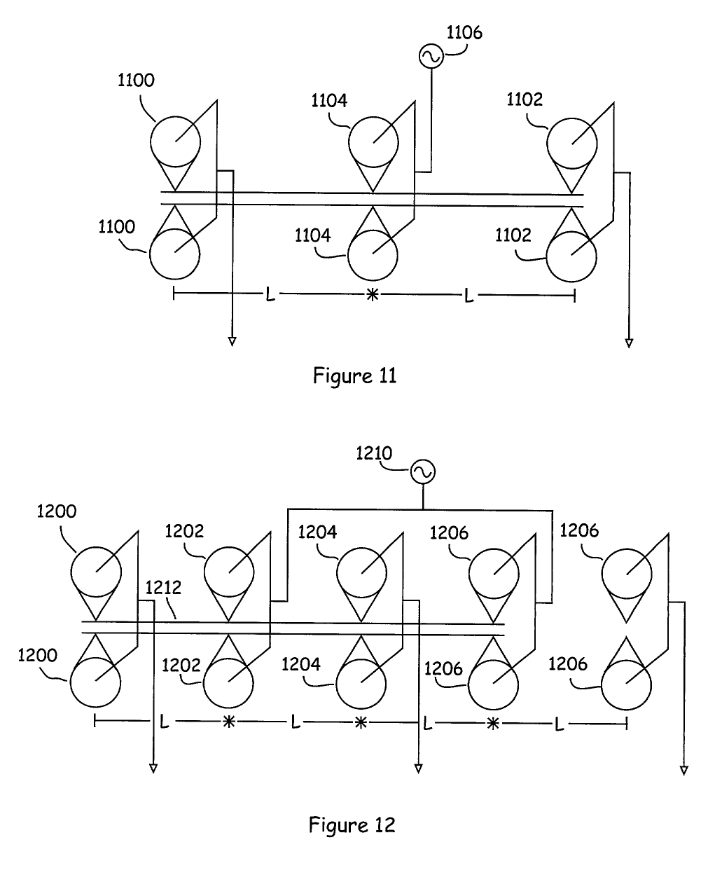

In certain embodiments, at least two of the at least three electrodes are directed to ground, e.g., to electrically isolate a heating segment of a microscale cavity. For example, in one embodiment, two of the three electrodes are peripheral electrodes, which peripheral electrodes are directed to ground. In this embodiment, at least one electrode disposed between the peripheral electrodes is typically directly connected to the electrical control system. This embodiment is depicted in FIG. 11 for a microchannel section that includes two electrically paralleled microchannel subsections, in which peripheral electrode pairs 1100 and 1102 are grounded and electrode pair 1104 is directly connected to electrical control system 1106. These electrode configurations insulate a heating segment of the microscale cavity that includes the at least three electrodes. As used herein, “electrode configuration” refers to a relative orientation or arrangement of electrodes within or proximal to microfluidic device cavities. Optionally, the microscale cavity includes more than three electrodes. For example, FIG. 12 includes five electrode pairs 1200, 1202, 1204, 1206, and 1208, respectively, disposed proximal to a section microchannel 1212, which includes four electrically paralleled microchannel subsections. As shown, in this embodiment, electrode pairs 1200, 1204, and 1208, are directed to ground, while electrode pairs 1202 and 1206 are directly connected to electrical control system 1210.

As noted, the microfluidic devices of the invention optionally include electrodes disposed within microscale cavities. For example, as shown in FIG. 8, four interdigitated electrodes (802, 804, 806, and 808, respectively) of microfluidic device 800 are utilized, e.g., to heat microchannel 810 which, as depicted, is about three times longer (i.e., includes three microchannel unit lengths, L) than the electrode configuration schematically illustrated in, e.g., FIG. 1, assuming distances between adjacent electrodes in FIGS. 1 and 8 are the same. Although the microchannel subsections disposed between electrodes 802 and 808 models approximately three times greater channel resistance than the section disposed between the electrode pairs depicted in FIG. 1, for the same applied voltage, the power dissipation (given by P =V²/R, described further above) per subsection is unchanged relative to the configuration of FIG. 1. Paralleled microscale cavity subsections that include electrodes disposed within the cavity are also optionally used to deliver current into device cavities via nonfaradaic pathways, which are discussed in greater detail below.

The microfluidic devices of the invention include various electrode geometries. An “electrode geometry,” as used herein, refers to the shape or form of a surface area of an electrode, e.g., exposed within or proximal to a microfluidic device cavity. For example, at least a fraction of each electrode generally includes at least one dimension of about 0.1 μm or less, e.g., to minimize the occurrence of bonding defects during device fabrication. Microfluidic device fabrication processes are described further below. In embodiments that include electrodes disposed within microscale cavities, the segment of each electrode exposed to fluidic materials in the microscale cavity typically includes a surface area of between about 1×10⁻⁶ cm² and about 100×10⁻⁴ cm². Additionally, in these embodiments, the segment of one or more electrodes also typically includes at least one shape selected from, e.g., a regular n-sided polygon, an irregular n-sided polygon, a triangle, a square, a rectangle, a trapezoid, a circle, a semi-circle, an oval, or the like. Furthermore, a segment of each electrode generally includes an inner layer and at least an outer layer. The outer layer typically includes, e.g., platinum disposed over the inner layer (e.g., a metal adhesion layer, such as titanium, tungsten, an alloy thereof, or the like). In certain embodiments, such as those including nonfaradaic electrodes (described below), the segment of one or more electrodes is present in a wide region of the microscale cavity in which the wide region is wider than an adjacent narrow region of the microscale cavity, e.g., to accommodate certain electrode geometries.

The present invention also provides a method of maintaining substantially constant power per subsection of a section of a microscale cavity (e.g., a microchannel, a capillary channel, a microscale reservoir, or the like) of a microfluidic device. The method includes flowing alternating current between segments of selected electrodes that are at least partially disposed within or proximal to the microscale cavity in which microscale cavity subsections disposed between adjacent electrodes are electrically in parallel with one another. A voltage gradient remains substantially constant independent of a length of the section of the microscale cavity. For example, a maximum applied voltage across the subsections of the microscale cavity is typically between about 100 V_{RMS} and about 10000 V_{RMS} (e.g., depending on subsection length). In addition, a sum of currents applied to the microscale cavity subsections is directly proportional to a length of the section of the microscale cavity. For example, a frequency of the alternating current is between about 1 KHz and about 100 KHz. Furthermore, a bulk fluid resistance within the microscale cavity is typically between about 0.1 Megohm/mm and about 100 Megohm/mm of cavity length.

The method of the invention also includes various electrode and microscale cavity configurations. For example, each microscale cavity subsection typically includes a length of between about 1 mm and about 100 mm. Optionally, electrodes are uniformly or non-uniformly spaced within or proximal to the microscale cavity. Additionally, the section of the microscale cavity optionally includes at least about 3, 4, 5, 6, or more electrodes.

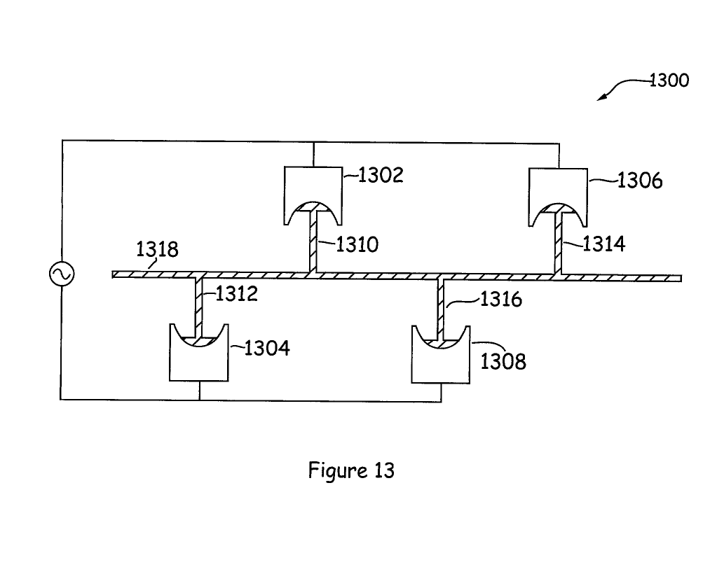

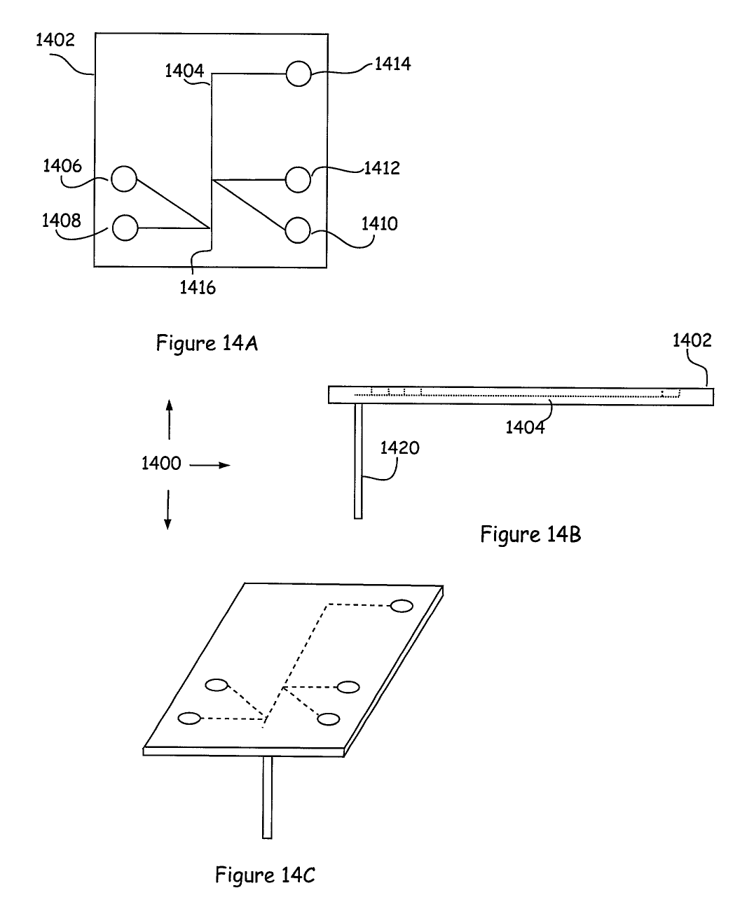

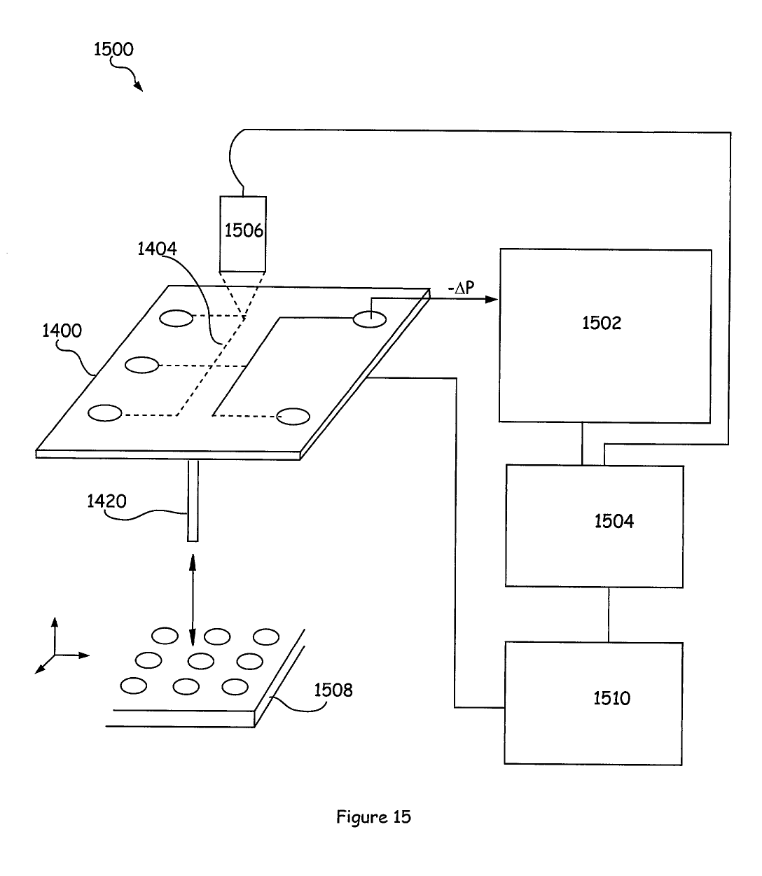

As described above for non-faradaic electrode configurations, the segmented electrode layouts described herein are also optionally set up to minimize slug dispersion, e.g., as shown in FIG. 7. For example, as shown in FIG. 13, microscale cavity configuration 1300 includes electrically paralleled cavity subsections disposed between electrodes 1302, 1304, 1306, and 1308, which are disposed in separate microscale cavities 1310, 1312, 1314, and 1316, respectively, which each fluidly communicate with main microscale cavity 1318 to minimize slug dispersion during fluid flow within main microscale cavity 1318. For example, at least a portion of at least one separate microscale cavity is optionally wider than a cross-section of main microscale cavity 1318, e.g., to accommodate an electrode, such as a nonfaradaic electrode described below. See, e.g., separate microscale cavities 1310, 1312, 1314, and 1316 in FIG. 13. The configuration depicted in FIG. 13 is electrically equivalent to the electrode configuration depicted in FIG. 8. As a result, the present invention optionally includes microfluidic devices configured, e.g., to resistively heat cavity segments, while minimizing slug dispersion and diffusion to improve the throughput and performance of various microfluidic analytical and preparative processes.

By parallelizing the electrodes used to impart current to different segments of an overall channel or channel system, one can reduce the level of applied voltage required to achieve a desired current. IN particular, in accordance with the invention, applied voltages at any of the electrodes are preferably maintained at or below 1000V, often, less than 500V, and in many cases, less than 100V.

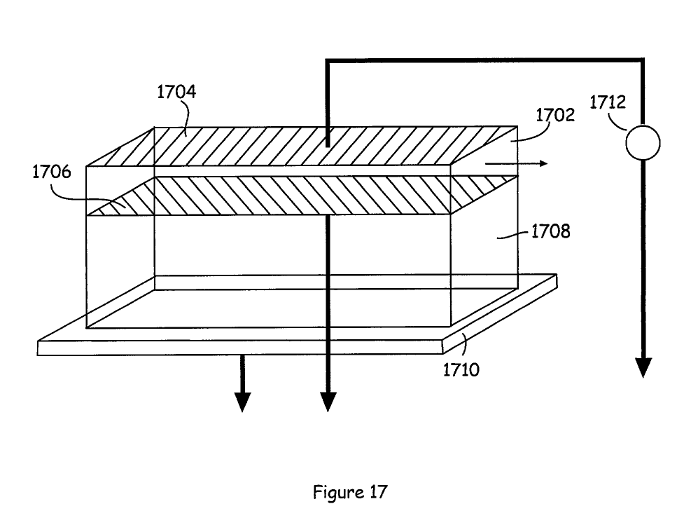

In still a further alternative arrangement, the invention provides a low impedance electrode configuration for imparting electric current through fluid containing cavities. In particular, in this aspect, the invention applies current through a cross-sectional dimension of a channel or cavity, e.g., width or depth, as opposed to a length dimension, e.g., as is shown in FIG. 1. In particular, by placing the electrodes on opposing sides or top and bottom of elongated fluid containing cavities, one shortens the resistive path between the electrodes, thus requiring lower applied voltages to achieve the same level of current. Further, in order to ensure heating of a larger section of channel, e.g., in order to ensure heating of adequate volumes of fluid, one can provide the electrode over large portions of the interior surface of the cavity or channel. FIG. 17 schematically illustrates a system 1700 that includes a segment of channel 1702. The channel includes two electrodes 1704 and 1706 disposed on opposing interior walls of the channel segment 1702, e.g., top and bottom, respectively. The electrodes are placed in facing opposition, meaning that there is a straight line for current flow through fluid between at least 85% of the current passing surface of each of the electrodes to the other electrode. The electrodes are operably coupled to an electrical power supply, e.g., AC source 1712. As shown, the channel segment 1702 is fabricated into or disposed over a substrate surface 1708, e.g., glass. FIG. 17 also shows a ground plane 1710 disposed beneath the channel segment 1702. Because the electrodes are only disposed a short distance apart, e.g., typically 2 to 100 μm in microscale systems, as opposed to millimeters or even centimeters, as is the case in FIG. 1, there is very little resistance between the electrodes. Accordingly, much lower voltages may be applied to achieve a desired current. The illustrated electrode configuration can be operated on stationary fluid volumes or on flowing fluid streams, e.g., as indicated by the arrow passing through channel segment 1702.

Under this aspect of the invention, benefit is derived not only from the potential of a greater relevant electrode surface area, but also by providing the electrode pairs for use in heating applications at relatively close proximity to each other. Typically, electrodes are positioned so as to maintain the between electrode resistances below about 100, and preferably, about 75 ohms.

While the invention is generally characterized in that it avoids excessive resistances between two opposing electrodes, in the context of biological applications, e.g., biochemical buffer systems, one can generalize acceptable distances between electrodes. For example, in particularly preferred aspects, the electrodes are maintained between about 2 and about 100 μm apart, and preferably between about 10 and about 50 μm apart, and more preferably, between about 10 and about 25 μm apart.

III. Temperature Control and Measurement

As mentioned above, resistive heating is typically produced by flowing AC through an electrode or other conductive component positioned within a well, channel, or other cavity within a given device. Alternating current is typically preferred for this application as it does not cause any electrokinetic movement of the fluid or other material that is to be heated. The resulting flow of alternating current resistively heats fluid within these cavities due to the reversal of charge relationships with each half-cycle, as negatively and positively charged ions are alternatively attracted to electrode surfaces. In this process, electrical energy is consumed and converted to heat by friction associated with the ionic movement. By substantially increasing the current across the channel, rapid temperature changes are induced that are optionally monitored by conductivity. Because nanoliter volumes of fluid disposed in device cavities have minute thermal masses, transitions between temperatures are typically extremely short. For example, oscillations between any two temperatures above 0° C. and below 100° C. in 100 milliseconds have been performed.

The present invention typically uses power sources that pass electrical current via nonfaradaic pathways through microchannels or other device cavities for heating purposes. In exemplary embodiments, fluid passes through a microchannel of a desired cross-section (e.g., diameter) to control transfer of thermal energy from the current to the fluid.

To selectively control the temperature of fluid in a region of a channel, a power supply applies voltage and/or current in various ways. For instance, a power supply optionally applies AC, which passes through the microchannel and into a microchannel region which is, e.g., smaller in cross-section to heat fluid in the region. Alternatively, a power supply applies a pulse or impulse of current and/or voltage, which passes through the microchannel and into a channel region to heat fluid in the region. Pulse width, shape, and/or intensity are optionally adjusted, e.g., to heat the fluid substantially while moving the fluid. Still further, the power supply optionally applies any combination of AC and pulse, depending upon the application. In practice, direct application of electric current to fluids in the microchannels of the invention results in extremely rapid and easily controlled changes in temperature.

A controller or computer such as a personal computer is generally used to monitor the temperature of the fluid in the region of the channel where the fluid is heated. The controller or computer typically receives current and voltage information from, e.g., the electrical control system and identifies or detects fluid temperature in the channel region. The controller or computer also typically receives current information from an operably connected detector, e.g., when a selected particle is detected, which triggers the flow of current through, e.g., one or more resistive heating electrodes. Depending upon the desired temperature of fluid in the region, the controller or computer adjusts voltage and/or current to meet the desired fluid temperature. Controllers and computers are discussed further below. Resistive heating in the context of microfluidic devices and systems is described further, e.g., in U.S. Pat. No. 5,965,410, entitled “Electrical Current for Controlling Fluid Parameters in Microchannels,” issued Oct. 12, 1999 to Chow et al. and in WO 98/45481, entitled “Closed-Loop Biochemical Analyzers,” filed Apr. 3, 1998, by Knapp et al., which are incorporated herein by reference in their entirety for all purposes.

Resistive heating is widely applicable, especially in the context of microfluidic devices. For example, nucleic acid amplification methods, such as the widely-known polymerase chain reaction (PCR) typically include repeated thermocycles that denature double-stranded target nucleic acids, hybridize single-stranded target and primer nucleic acids, and elongate primer strands with a polymerase. Many variations of this basic technique are also known, including asymmetric PCRs, assembly PCRs, reverse transcription PCRs (RT-PCRs), ligase chain reactions (LCRs), or the like. All of these techniques are optionally adapted to the high-throughput devices and methods of the present invention.

MICROFLUIDIC DEVICES

Many different microscale systems are optionally adapted for use with the methods and devices for preferentially providing nonfaradaic current of the present invention. These systems are described in detail in various published PCT applications and issued U.S. Patents 10 owned by Caliper Technologies Corp., and accessible from the U.S. Patent and Trademark Office Website at www.USPTO.gov. These microfluidic systems are optionally and readily adapted to the present invention by, e.g., incorporating any of the nonfaradaic electrode and system configurations described herein to minimize water hydrolysis and gas formation during resistive heating, electrokinetic transport, or other microfluidic applications, or to incorporate segmenting approaches to the application of current to fluids.

The methods of the invention are generally performed within fluidic channels in which fluids including, e.g., reagents, enzymes, samples, and other materials, are disposed and/or flowed. In some cases, the channels are simply present in a capillary or pipettor element, e.g., a glass, fused silica, quartz or plastic capillary. The capillary element is fluidly coupled to a source of fluid, which is then flowed along the channel (e.g., a microchannel) of the element. In preferred embodiments, the fluidic channel is integrated into the body structure of a microfluidic device. The term “microfluidic,” as used herein, generally refers to one or more fluid passages, chambers or conduits which have at least one internal cross-sectional dimension, e.g., depth, width, length, diameter, etc., that is less than 500 μm, and typically between about 0.1 μm and about 500 μm.

In the devices of the present invention, the microscale cavities (e.g., microchannels, capillary channels, microscale reservoirs, or the like) typically have at least one cross-sectional dimension between about 0.1 μm and 200 μm, preferably between about 0.1 μm and 100 μm, and often between about 0.1 μm and 50 μm. Accordingly, the microfluidic devices or systems prepared in accordance with the present invention typically include at least one microscale channel, usually at least two intersecting microscale channels, and often, three or more intersecting channels disposed within a single body structure. Channel intersections may exist in a number of formats, including cross intersections, “Y” and/or “T” intersections, or any number of other structures whereby two channels are in fluid communication.

The body structures of the microfluidic devices described herein are typically manufactured from two or more separate portions or substrates which when appropriately mated or joined together, form the microfluidic device of the invention, e.g., containing the channels and/or chambers and the electrodes described herein. During body structure fabrication, the microfluidic devices described herein will typically include a top portion, a bottom portion, and an interior portion, wherein the interior portion substantially defines the channels and chambers of the device.

In one aspect, a bottom portion of the unfinished device includes a solid substrate that is substantially planar in structure, and which has at least one substantially flat upper surface. Channels are typically fabricated on one surface of the device and sealed by overlaying the channels with an upper substrate layer. A variety of substrate materials are optionally employed as the upper or bottom portion of the device. Typically, because the devices are microfabricated, substrate materials will be selected based upon their compatibility with known microfabrication techniques, e.g., photolithography, wet chemical etching, laser ablation, air abrasion techniques, LIGA, reactive ion etching, injection molding, embossing, and other techniques. The substrate materials are also generally selected for their compatibility with the full range of conditions to which the microfluidic devices may be exposed, including extremes of pH, temperature, electrolyte concentration, and/or for their chromatographic properties. Accordingly, in some preferred aspects, the substrate material may include materials normally associated with the semiconductor industry in which such microfabrication techniques are regularly employed, including, e.g., silica-based substrates, such as glass, quartz, silicon or polysilicon, as well as other substrate materials, such as gallium arsenide and the like. In the case of semiconductive materials, it will often be desirable to provide an insulating coating or layer, e.g., silicon oxide, over the substrate material, and particularly in those applications where electric fields are to be applied to the device or its contents.

In additional preferred aspects, the substrate materials will comprise polymeric materials, e.g., plastics, such as polymethylmethacrylate (PMMA), polycarbonate, polytetrafluoroethylene (TEFLON™), polyvinylchloride (PVC), polydimethylsiloxane (PDMS), polysulfone, polystyrene, polymethylpentene, polypropylene, polyethylene, polyvinylidine fluoride, ABS (acrylonitrile-butadiene-styrene copolymer), and the like. In preferred embodiments, at least the separation region(s) is/are fabricated from polyacrylamide, dimethylacrylamide, modified versions thereof, nonionic detergents, ionic detergents, or the like. Such polymeric substrates are readily manufactured using available microfabrication techniques, as described above, or from microfabricated masters, using known molding techniques, such as injection molding, embossing or stamping, or by polymerizing the polymeric precursor material within the mold (see, e.g. U.S. Pat. No. 5,512,131). Such polymeric substrate materials are preferred for their ease of manufacture, low cost and disposability, as well as their general inertness to most extreme reaction conditions. Again, these polymeric materials optionally include treated surfaces, e.g., derivatized or coated surfaces, to enhance their utility in the microfluidic system, e.g., to provide enhanced fluid direction, e.g., as described in U.S. Pat. No. 5,885,470 (J. Wallace Parce et al.) issued Mar. 23 1999, and which is incorporated herein by reference in its entirety for all purposes.

The channels and/or cavities of the microfluidic devices are typically fabricated into the upper surface of the bottom substrate or portion of the device, as microscale grooves or indentations, using the above described microfabrication techniques. The top portion or substrate also comprises a first planar surface, and a second surface opposite the first planar surface. In the microfluidic devices prepared in accordance with certain aspects of the methods described herein, the top portion can include at least one aperture, hole or port disposed therethrough, e.g., from the first planar surface to the second surface opposite the first planar surface. In other embodiments, the port(s) are optionally omitted, e.g., where fluids are introduced solely through external capillary elements.

The first planar surface of the top portion or substrate is then mated, e.g., placed into contact with, and bonded to the planar surface of the bottom substrate, covering and sealing the grooves and/or indentations in the surface of the bottom substrate, to form the channels and/or chambers (i.e., the interior portion) of the device at the interface of these two components. The electrodes (e.g., nonfaradaic, and optionally, ground and/or faradaic electrodes) described herein are typically disposed relative to the grooves and/or indentations in the surface of the bottom substrate before the top and bottom substrates are mated and bonded. Optionally, the electrodes or portions thereof are not covered by the top substrates. For example, a top substrate is optionally placed adjacent to an electrode disposed relative to the grooves and/or indentations in the surface of the bottom substrate. As mentioned, these electrodes are generally patterned metal layers of essentially any geometric shape. For example, portions of electrodes exposed to fluidic materials in device cavities typically include surface areas between about 1×10⁻⁶ cm² and about 100×10⁻⁴ cm². Additionally, at least segments of the electrodes optionally include an outer layer (e.g., platinum, etc.) disposed over an inner layer (e.g., a metal adhesion layer, such as titanium, tungsten, an alloy thereof, or the like). Incorporated electrodes typically include thicknesses of at most about 0.1 μm to properly form device cavities and to avoid the formation of bond voids upon substrate bonding. Techniques for fabricating electrodes suitable for the present invention are generally known. Bonding of substrates is typically carried out by any of a number of different methods, e.g., thermal bonding, solvent bonding, ultrasonic welding, and the like. The finished body structure of a device is a unitary structure that houses, e.g., the channels and/or chambers and electrodes of the device.

The hole(s) in the top of the finished device is/are oriented to fluidly communicate with at least one of the channels and/or cavities. In the completed device, the hole(s) optionally function as reservoirs for facilitating fluid or material introduction into the channels or chambers of the device, as well as providing ports at which, e.g., pressure elements (e.g., vacuum sources, etc.) are optionally placed into contact with fluids within the device, allowing application of pressure gradients along the channels of the device to control and direct fluid transport within the device. In optional embodiments, extensions are provided over these reservoirs to allow for increased fluid volumes, permitting longer running assays, and better controlling fluid flow parameters, e.g., hydrostatic pressures. Examples of methods and apparatuses for providing such extensions are described in U.S. application Ser. No. 09/028,965, filed Feb. 24, 1998, and incorporated herein by reference. These devices are optionally coupled to a sample introduction port, e.g., a pipettor or capillary element, which serially introduces multiple samples, e.g., from the wells of a microtiter plate. Thus, in some embodiments, both reservoirs in the upper surface and external capillary elements are present in a single device.

The sources of electrolytes and other materials are optionally fluidly coupled to the microchannels in any of a variety of ways. In particular, those systems comprising sources of materials set forth in Knapp et al. “Closed Loop Biochemical Analyzers” (WO 98/45481; PCT/US98/06723) and U.S. Pat. No. 5,942,443 issued Aug. 24, 1999, entitled “High Throughput Screening Assay Systems in Microscale Fluidic Devices” to J. Wallace Parce et al. and, e.g., in 60/128,643 filed Apr. 4, 1999, entitled “Manipulation of Microparticles In Microfluidic Systems,” by Mehta et al. are applicable.

In these systems and as noted above, a capillary or pipettor element (i.e., an element in which components are optionally moved from a source to a microscale element such as a second channel or reservoir) is temporarily or permanently coupled to a source of material. The source is optionally internal or external to a microfluidic device that includes the pipettor or capillary element. Example sources include microwell plates, membranes or other solid substrates comprising lyophilized components, wells or reservoirs in the body of the microscale device itself and others.

Flow of Materials in Microfluidic Devices

The flowing of electrolytes or other materials in the cavities of the devices described herein is optionally carried out by a number of mechanisms, including pressure-based flow, electrokinetic flow, hydrodynamic flow, gravity-based flow, centripetal or centrifugal flow, or mechanisms that utilize hybrids of these techniques. In a preferred aspect, a pressure differential is used to flow the materials along, e.g., a capillary element or other channel.

The application of a pressure differential along the channel is carried out by any of a number of approaches. For example, it may be desirable to provide relatively precise control of the flow rate of samples and/or other reagents, e.g., to precisely control incubation or separation times, or the like depending on the particular assay being performed. As such, in many preferred aspects, flow systems that are more active than hydrostatic pressure driven systems are employed. In certain cases, materials may be flowed by applying a pressure differential across the length of a given channel. For example, a pressure source (positive or negative) is applied at the material reservoir at one end of a channel, and the applied pressure forces the materials through the channel. The pressure source is optionally pneumatic, e.g., a pressurized gas, or a positive displacement mechanism, i.e., a plunger fitted into a material reservoir, for forcing the materials through the channel. Alternatively, a vacuum source is applied to a reservoir at the opposite end of the channel to draw the materials through the channel. Pressure or vacuum sources may be supplied external to the device or system, e.g., external vacuum or pressure pumps sealably fitted to the inlet or outlet of the channel, or they may be internal to the device, e.g., microfabricated pumps integrated into the device and operably linked to the channel. Examples of microfabricated pumps have been widely described in the art. See, e.g., published International Application No. WO 97/02357.

In an alternative simple passive aspect, the materials are deposited in a reservoir or well at one end of a channel and at a sufficient volume or depth, that the material sample creates a hydrostatic pressure differential along the length of the channel, e.g., by virtue of it having greater depth than a reservoir at an opposite terminus of the channel. The hydrostatic pressure then causes the materials to flow along the length of the channel. Typically, the reservoir volume is quite large in comparison to the volume or flow through rate of the channel, e.g., 10 μl reservoirs, vs. 1000 μm² channel cross-section. As such, over the time course of the assay, the flow rate of the materials will remain substantially constant, as the volume of the reservoir, and thus, the hydrostatic pressure changes very slowly. Applied pressure is then readily varied to yield different material flow rates through the channel. In screening applications, varying the flow rate of the materials is optionally used to vary the incubation time of the materials. In particular, by slowing the flow rate along the channel, one can effectively lengthen the amount of time between introduction of materials and detection of a particular effect. Alternatively, channel lengths, detection points, or material introduction points are varied in fabrication of the devices, to vary incubation times. See also, “Multiport Pressure Control System,” by Chien and Parce, U.S. Ser. No. 60/184,390, filed Feb. 23, 2000, which describes multiport pressure controllers that couple pumps to multiple device reservoirs.

In further alternate aspects, other flow systems are employed in transporting materials through the device channels or cavities. One example of such alternate methods employs electrokinetic forces to transport the materials. Electrokinetic transport systems typically utilize electric fields applied along the length of channels that have a surface potential or charge associated therewith. When fluid is introduced into the channel, the charged groups on the inner surface of the channel ionize, creating locally concentrated levels of ions near the fluid surface interface. Under an electric field, this charged sheath migrates toward the cathode or anode (depending upon whether the sheath comprises positive or negative ions) and pulls the encompassed fluid along with it, resulting in bulk fluid flow. This flow of fluid is generally termed electroosmotic flow. Where the fluid includes materials, the materials are also pulled along. A more detailed description of controlled electrokinetic material transport systems in microfluidic systems is described in published International Patent Application No. WO 96/04547, which is incorporated herein by reference.

Hydrostatic, wicking and capillary forces are also optionally used to provide for fluid flow. See, e.g., “Method and Apparatus for Continuous Liquid Flow in Microscale Channels Using Pressure Injection, Wicking and Electrokinetic Injection,” by Alajoki et al., U.S. Ser. No. 09/245,627, filed Feb. 5, 1999. In these methods, an adsorbent material or branched capillary structure is placed in fluidic contact with a region where pressure is applied, thereby causing fluid to move towards the adsorbent material or branched capillary structure.

In alternative aspects, flow of materials is driven by inertial forces. In particular, a device cavity or channel is optionally disposed in a substrate that has the conformation of a rotor, with the cavity or channel extending radially outward from the center of the rotor. The materials are deposited in a reservoir that is located at the interior portion of the rotor and is fluidly connected to the cavity or channel. During rotation of the rotor, the centripetal force on the materials forces the reagents through the cavity or channel, outward toward the edge of the rotor. Multiple cavities or channels are optionally provided in the rotor to perform multiple different analyses. Detection of a detectable signal produced by the materials is then carried out by placing a detector under the spinning rotor and detecting the signal as the cavity or channel passes over the detector. Examples of rotor systems have been previously described for performing a number of different assay types. See, e.g., Published International Application No. WO 95/02189. Test compound reservoirs are optionally provided in the rotor, in fluid communication with the cavity or channel, such that the rotation of the rotor also forces the test compounds into the cavity or channel.

For purposes of illustration the discussion has focused on a single cavity or channel and accessing capillary, however, it will be readily appreciated that these aspects may be provided as multiple parallel channels and accessing capillaries, in order to substantially increase the throughput of the system. Specifically, single body structures may be provided with multiple parallel channels coupled to multiple sample accessing capillaries that are positioned to sample multiple samples at a time from sample libraries, e.g., multiwell plates or other array formats. As such, these capillaries are generally spaced at regular distances that correspond with the spacing of wells in, e.g., multiwell plates, e.g., 9 mm centers for 96 well plates, 4.5 mm for 384 well plates, and 2.25 mm for 1536 well plates.

Devices and Integrated Systems

The present invention also relates to integrated systems that are typically used to perform the high-throughput analyses, assays, and other processes described above and in the publications cited herein, which incorporate the devices of the invention. The microfluidic devices each typically include a substrate having a surface with at least one microscale cavity fabricated into the surface of the substrate in which the microscale cavity includes at least one incorporated nonfaradaic electrode configuration, and a cover mated and bonded with the surface of the substrate. Microfluidic device fabrication, and electrode geometries and configurations, are described in greater detail above. The device also typically includes an electrical control system (e.g., an alternating current source) operably connected to at least one nonfaradaic electrode for preferentially delivering current to the cavity through nonfaradiac pathways, e.g., to resistively heat fluidic materials within at least a portion of the cavity. The devices of the invention also generally include a source of an electrolyte in fluid communication with the microscale cavity (e.g., via a capillary element or the like) and a fluid direction system (e.g., a fluid pressure force modulator, an electrokinetic force modulator, or the like) operably connected to the microfluidic device for inducing flow of the material in the microscale cavity. In certain embodiments, the microfluidic device includes a plurality of parallel microchannels fabricated into the surface of the substrate in which each parallel microchannel includes at least one nonfaradaic electrode configuration, e.g., for performing multiple assays simultaneously to enhance device throughput.

The microfluidic devices of the invention also typically include an integrated system. The system generally includes a computer or a computer readable medium that includes at least one instruction set for selectively activating or deactivating current flow and a controller/detector apparatus configured to receive the microfluidic device. The controller/detector apparatus typically includes a detection system and a material transport system in which the detection and transport systems are operably interfaced with the microfluidic device.

The present invention, in addition to other integrated system components, also optionally includes a microfluidic device handling system for performing the methods disclosed herein. Specifically, the microfluidic device handling system includes a holder configured to receive the microfluidic device, a container sampling region proximal to the holder, and the controller. During operation of the handling system, the controller directs, e.g., dipping of microfluidic device capillary or pipettor element(s) into a portion of, e.g., a microwell plate in the container sampling region. The microfluidic device handling system also optionally includes a computer or a computer readable medium operably connected to the controller. The computer or the computer readable medium typically includes an instruction set for varying or selecting a rate or a mode of dipping capillary element(s) into fluid materials.

Although the devices and systems specifically illustrated herein are generally described in terms of the performance of a few or one particular operation, it will be readily appreciated from this disclosure that the flexibility of these systems permits easy integration of additional operations into these devices. For example, the devices and systems described will optionally include structures, reagents and systems for performing virtually any number of operations in addition to the operations specifically described herein. Aside from fluid handling, amplification, sequencing, and separation of sample and/or reaction components, other upstream or downstream operations include, e.g., extraction, purification, cellular activation, labeling reactions, dilution, aliquotting, labeling of components, assays and detection operations, electrokinetic or pressure-based injection of components or materials into contact with one another, or the like. Assay and detection operations include, without limitation, cell fluorescence assays, cell activity assays, receptor/ligand assays, immunoassays, or the like.

In the present invention, the materials are optionally monitored and/or detected so that, e.g., an activity can be determined. The systems described herein generally include microfluidic device handling systems, as described above, in conjunction with additional instrumentation for controlling fluid transport, flow rate and direction within the devices, detection instrumentation for detecting or sensing results of the operations performed by the system, processors, e.g., computers, for instructing the controlling instrumentation in accordance with preprogrammed instructions, receiving data from the detection instrumentation, and for analyzing, storing and interpreting the data, and providing the data and interpretations in a readily accessible reporting format.

Controllers

The controllers of the integrated systems of the invention are generally utilized, e.g., to regulate the activation and deactivation of AC flow to nonfaradaic electrode configurations. Controllers also typically direct dipping of capillary elements into, e.g., microwell plates to sample materials, such as enzymes and nucleic acids, fluid recirculation baths or troughs, or the like. A variety of controlling instrumentation is also optionally utilized in conjunction with the microfluidic devices and handling systems described herein, for controlling the transport, capture, concentration, direction, and motion of fluids within the devices of the present invention, e.g., by pressure-based control.

As described above, in many cases, fluid transport, capture, concentration, and direction are controlled in whole or in part, using pressure-based flow systems that incorporate external or internal pressure sources to drive fluid flow. Internal sources include microfabricated pumps, e.g., diaphragm pumps, thermal pumps, and the like that have been described in the art. See, e.g., U.S. Pat. Nos. 5,271,724, 5,277,556, and 5,375,979 and Published PCT Application Nos. WO 94/05414 and WO 97/02357. Preferably, external pressure sources are used, and applied to ports at channel termini. These applied pressures, or vacuums, generate pressure differentials across the lengths of channels to drive fluid flow through them. In the interconnected channel networks described herein, differential flow rates on volumes are optionally accomplished by applying different pressures or vacuums at multiple ports, or preferably, by applying a single vacuum at a common waste port and configuring the various channels with appropriate resistance to yield desired flow rates. Example systems are also described in U.S. Ser. No. 09/238,467 filed Jan. 1 28 1999.

Typically, the controller systems are appropriately configured to receive or interface with a microfluidic device or system element as described herein. For example, the controller and/or detector, optionally includes a stage upon which the device of the invention is mounted to facilitate appropriate interfacing between the controller and/or detector and the device. Typically, the stage includes an appropriate mounting/alignment structural element, such as a nesting well, alignment pins and/or holes, asymmetric edge structures (to facilitate proper device alignment), and the like. Many such configurations are described in the references cited herein.

The controlling instrumentation discussed above is also used to provide for electrokinetic injection or withdrawal of material downstream of the region of interest to control an upstream flow rate. The same instrumentation and techniques described above are also utilized to inject a fluid into a downstream port to function as a flow control element. A variety of electrokinetic controllers and electrical control systems which are optionally used in the present invention e.g., to resistively heat materials, or the like are described, e.g., in Ramsey WO 96/04547, Parce et al. WO 98/46438 and Dubrow et al., WO 98/49548, as well as a variety of other references noted herein.

Detector

The devices described herein optionally include signal detectors, e.g., which detect concentration, fluorescence, phosphorescence, radioactivity, pH, charge, absorbance, refractive index, luminescence, temperature, magnetism, mass (e.g., mass spectrometry), or the like. The detector(s) optionally monitors one or a plurality of signals from upstream and/or downstream of an assay mixing point in which, e.g., a substrate nucleic acid, an enzyme, and other reaction components are mixed. For example, the detector optionally monitors a plurality of optical signals which correspond in position to “real time” assay/separation results.

Example detectors or sensors include photomultiplier tubes, CCD arrays, optical sensors, temperature sensors, pressure sensors, pH sensors, conductivity sensors, mass sensors, scanning detectors, or the like. Materials which emit a detectable signal are optionally flowed past the detector, or, alternatively, the detector can move relative to the device to determine the position of an assay component (or, the detector can simultaneously monitor a number of spatial positions corresponding to channel regions, e.g., as in a CCD array). Each of these types of sensors is optionally readily incorporated into the microfluidic systems described herein. In these systems, such detectors are placed either within or adjacent to the microfluidic device or one or more channels, chambers or conduits of the device, such that the detector is within sensory communication with the device, channel, or chamber. The phrase “within sensory communication” of a particular region or element, as used herein, generally refers to the placement of the detector in a position such that the detector is capable of detecting the property of the microfluidic device, a portion of the microfluidic device, or the contents of a portion of the microfluidic device, for which that detector was intended. The detector optionally includes or is operably linked to a computer, e.g., which has software for converting detector signal information into assay result information (e.g., kinetic data of modulator activity), or the like. A microfluidic system optionally employs multiple different detection systems for monitoring the output of the system. Detection systems of the present invention are used to detect and monitor the materials in a particular channel region (or other reaction detection region).

The detector optionally exists as a separate unit, but is preferably integrated with the controller system, into a single instrument. Integration of these functions into a single unit facilitates connection of these instruments with the computer (described below), by permitting the use of few or a single communication port(s) for transmitting information between the controller, the detector, and the computer.

Specific detection systems that are optionally used in the present invention include, e.g., an emission spectroscope, a fluorescence spectroscope, a phosphorescence spectroscope, a luminescence spectroscope, a spectrophotometer, a photometer, a nuclear magnetic resonance spectrometer, an electron paramagnetic resonance spectrometer, an electron spin resonance spectroscope, a turbidimeter, a nephelometer, a Raman spectroscope, a refractometer, an interferometer, an x-ray diffraction analyzer, an electron diffraction analyzer, a polarimeter, an optical rotary dispersion analyzer, a circular dichroism spectrometer, a potentiometer, a chronopotentiometer, a coulometer, an amperometer, a conductometer, a gravimeter, a mass spectrometer, a thermal gravimeter, a titrimeter, a differential scanning calorimeter, a radioactive activation analyzer, a radioactive isotopic dilution analyzer, or the like.

Computer

As noted above, the microfluidic devices and integrated systems of the present invention optionally include a computer operably connected to at least one controller. The computer typically includes instruction sets for effecting, e.g., the activation and/or deactivation of current flow to selected electrodes, the regulation of pressure-based fluid flow, the control of device temperatures, the variation or selection of a rate or a mode of dipping capillary or pipettor elements into fluid materials, the sampling of fluidic materials, or the like. Additionally, either or both of the controller system and/or the detection system is/are optionally coupled to an appropriately programmed processor or computer which functions to instruct the operation of these instruments in accordance with preprogrammed or user input instructions, receive data and information from these instruments, and interpret, manipulate and report this information to the user. As such, the computer is typically appropriately coupled to one or both of these instruments (e.g., including an analog to digital or digital to analog converter as needed).

The computer typically includes appropriate software for receiving user instructions, either in the form of user input into a set parameter fields, e.g., in a GUI, or in the form of preprogrammed instructions, e.g., preprogrammed for a variety of different specific operations. The software then converts these instructions to appropriate language for instructing the operation of the electrical control system, fluid direction, and transport controller(s) to carry out the desired operation, e.g., activating and/or deactivating AC flow to nonfaradaic electrode configurations, varying or selecting the rate or mode of fluid and/or microfluidic device movement, controlling flow rates within microscale channels, directing X-Y-Z translation of the microfluidic device or of one or more microwell plates, or the like. The computer then receives the data from the one or more sensors/detectors included within the system, and interprets the data, either provides it in a user understood format, or uses that data to initiate farther controller instructions, in accordance with the programming, e.g., such as in monitoring and control of flow rates, temperatures, applied voltages, or the like. In particular, detectors are utilized to monitor potential drops across nonfaradaic electrode/electrolyte interfaces and in accordance with appropriate programming instructions, the computer uses the data received from these detectors to maintain potentials below the activation energy threshold of faradaic pathways at these interfaces to effect shunting of current to nonfaradaic pathways. Additionally, the software is optionally used to control, e.g., pressure or electrokinetic modulated injection or withdrawal of material.

Example Integrated System

FIG. 9, Panels A, B, and C and FIG. 10 provide additional details regarding example integrated systems that are optionally used to practice the methods herein. As shown, body structure 902 of microfluidic device 900 has main microchannel 904 disposed therein. Although not shown, nonfaradaic electrode configurations, as described herein, are included in the devices of the invention. An electrolyte or other material is optionally flowed from pipettor or capillary element 920 towards reservoir 914, e.g., by applying a vacuum at reservoir 914 (or another point in the system) and/or by applying appropriate voltage gradients. Alternatively, a vacuum is applied at reservoirs 908, 912 or through pipettor or capillary element 920. Additional materials are optionally flowed from wells 908 or 912 and into main microchannel 904. Flow from these wells is optionally performed by modulating fluid pressure, or by electrokinetic approaches as described (or both). As fluid is added to main microchannel 904, e.g., from reservoir 908, the flow rate increases. The flow rate is optionally reduced by flowing a portion of the fluid from main microchannel 904 into flow reduction microchannel 906 or 910. The arrangement of channels depicted in FIG. 9 is only one possible arrangement out of many which are appropriate and available for use in the present invention. Additional alternatives can be devised, e.g., by combining the microfluidic elements described herein, e.g., nonfaradaic electrode configurations or the like, with other microfluidic device components described in the patents and applications referenced herein.

Samples or other materials are optionally flowed from the enumerated wells or from a source external to the body structure. As depicted, the integrated system optionally includes pipettor or capillary element 920, e.g., protruding from body 902, for accessing a source of materials external to the microfluidic system. Typically, the external source is a microtiter dish, a substrate, a membrane, or other convenient storage medium. For example, as depicted in FIG. 10, pipettor or capillary element 920 can access microwell plate 1008, which includes sample materials, buffers, substrate solutions, enzyme solutions, or the like, in the wells of the plate.

Detector 1006 is in sensory communication with main microchannel 904, detecting signals resulting, e.g., from labeled materials flowing through the detection region. Detector 1006 is optionally coupled to any of the channels or regions of the device where detection is desired. Detector 1006 is operably linked to computer 1004, which digitizes, stores, and manipulates signal information detected by detector 1006, e.g., using any instruction set, e.g., for determining concentration, molecular weight or identity, or the like.

Fluid direction system 1002 controls pressure, voltage, or both, e.g., at the wells of the system or through the channels or other cavities of the system, or at vacuum couplings fluidly coupled to main microchannel 904 or other channels described above. Optionally, as depicted, computer 1004 controls fluid direction system 1002. In one set of embodiments, computer 1004 uses signal information to select further parameters for the microfluidic system. For example, upon detecting the presence of a component of interest (e.g., following separation) in a sample from microwell plate 1008, the computer optionally directs addition of a potential modulator of the component of interest into the system. In certain embodiments, controller 1010 dispenses aliquots of selected material into, e.g., main microchannel 904. In these embodiments, controller 1010 is also typically operably connected to computer 1004, which directs controller 1010 function.

Although not shown, a microfluidic device handling system is also included in the integrated systems of the present invention. Microfluidic device handling systems generally control, e.g., the X-Y-Z translation of microfluidic device 900 relative to microwell plate 1008, of microwell plate 1008 relative to microfluidic device 900, or of other system components, under the direction of computer 1004, e.g., according to appropriate program instructions, to which device handling systems are typically operably connected.

Kits

Generally, the microfluidic devices described herein are optionally packaged to include reagents for performing the device's preferred function. For example, the kits can include any of microfluidic devices described along with assay components, reagents, sample materials, particle sets, salts, separation matrices, control/calibrating materials, or the like. Such kits also typically include appropriate instructions for using the devices and reagents, and in cases where 15S reagents are not predisposed in the devices themselves, with appropriate instructions for introducing the reagents into the channels and/or chambers of the device. In this latter case, these kits optionally include special ancillary devices for introducing materials into the microfluidic systems, e.g., appropriately configured syringes/pumps, or the like (in one preferred embodiment, the device itself comprises a pipettor element, such as an electropipettor for introducing material into channels and chambers within the device). In the former case, such kits typically include a microfluidic device with necessary reagents predisposed in the channels/chambers of the device. Generally, such reagents are provided in a stabilized form, so as to prevent degradation or other loss during prolonged storage, e.g., from leakage. A number of stabilizing processes are widely used for reagents that are to be stored, such as the inclusion of chemical stabilizers (i.e., enzymatic inhibitors, microcides/bacteriostats, anticoagulants), the physical stabilization of the material, e.g., through immobilization on a solid support, entrapment in a matrix (i.e., a gel), lyophilization, or the like. Kits also optionally include packaging materials or containers for holding a microfluidic device, system or reagent elements.

### EXAMPLES

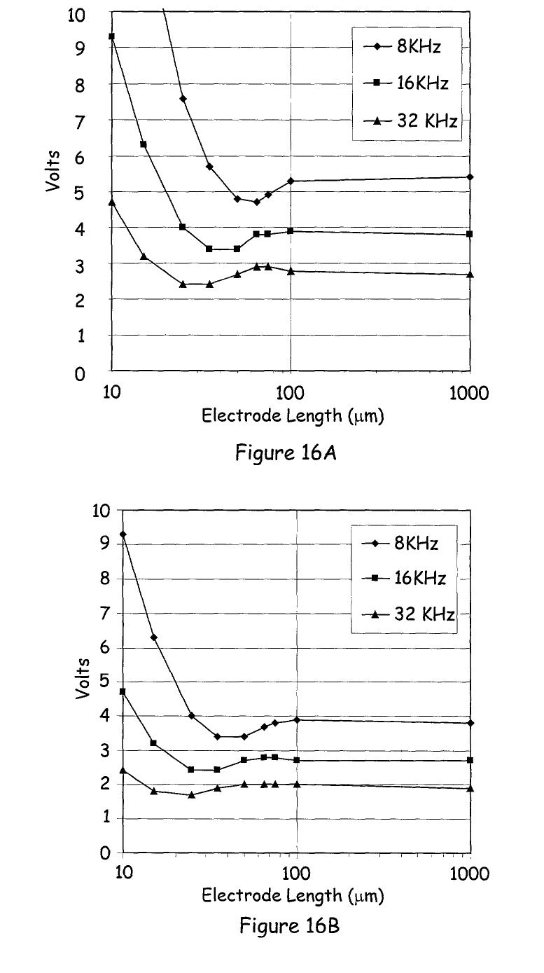

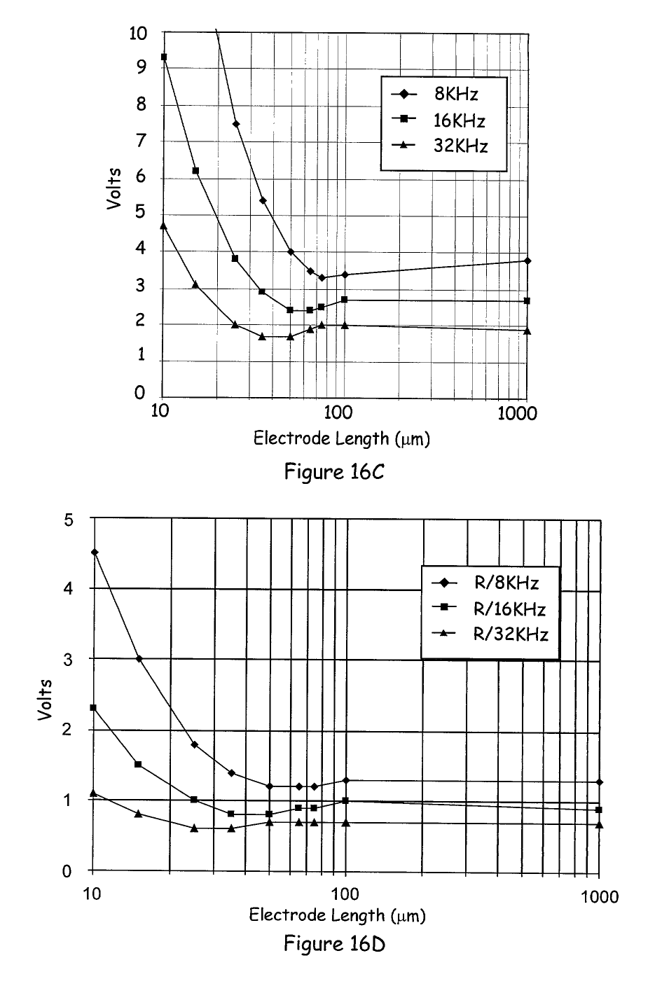

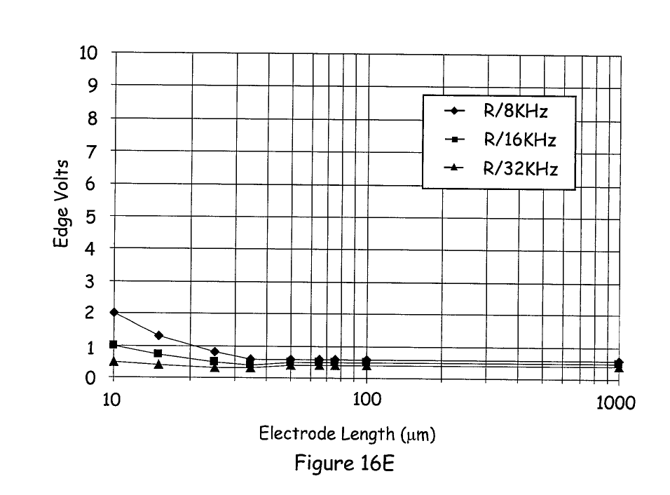

FIGS. 16A-E provide line plots of uniform RC Spice models that indicate the relative co-variances of voltage and electrode length for 8 KHz, 16 KHz, and 32 KHz AC frequencies, respectively. The models shown in FIGS. 16A-C are for electrodes having widths of 80 μm and which are disposed in microscale cavities having depths of 15 μm. In particular, FIG. 16A shows the results for electrodes that include a capacitance per unit length of 16 pF/μm and a resistance per unit length of 1000 Ω/μm. FIG. 16B shows the results for electrodes that include a capacitance per unit length of 32 pF/μm and a resistance per unit length of 1000 Ω/μm. FIG. 16C shows the results for electrodes that include a capacitance per unit length of 16 pF/μm and a resistance per unit length of 500 Ω/μm. FIG. 16D shows the results for electrodes having widths of 300 μm and which are disposed in microscale cavities having depths of 15 μm. The electrodes of FIG. 16D include a capacitance per unit length of 60 pF/μm and a resistance per unit length of 242 Ω/μm. FIG. 16E shows the results for electrodes having widths of 500 μm and which are disposed in microscale cavities having depths of 15 μm. The electrodes of FIG. 16E include a capacitance per unit length of 106 pF/μm and a resistance per unit length of 151 Ω/μm.

While the foregoing invention has been described in some detail for purposes of clarity and understanding, it will be clear to one skilled in the art from a reading of this disclosure that various changes in form and detail can be made without departing from the true scope of the invention. For example, all the techniques and apparatus described above may be used in various combinations. All publications, patents, patent applications, or other documents cited in this application are incorporated by reference in their entirety for all purposes to the same extent as if each individual publication, patent, patent application, or other document were individually indicated to be incorporated by reference for all purposes.

What is claimed is:

1. A method for applying an electrical current through a fluid containing cavity, comprising:
providing a fluid containing cavity;
contacting at least first and second electrodes with the fluid in the fluid containing cavity, the first electrode having a relevant surface area in contact with the fluid in the fluid containing cavity and the second electrode having a second relevant surface area in contact with the fluid in the fluid containing cavity;
applying an alternating current to the fluid in the fluid containing cavity through the first and second electrodes at a first frequency; and
wherein the first frequency and the relevant surface area is selected to avoid generation of gas bubbles at either of the first and second electrodes.

2. The method of claim 1, wherein the first frequency is greater than 1 KHz.

3. The method of claim 1, wherein the first frequency is greater than 5 KHz.

4. The method of claim 1, wherein the first and second electrodes are patterned on a first surface of the fluid containing cavity and the relevant surface area comprises a first edge of the first electrode that faces the second electrode along a path of the electrical current.

5. The method of claim 4, wherein the first edge of the first electrode is configured to provide substantially uniform current distribution across the first edge.

6. The method of claim 5, wherein the first electrode is disposed in a first portion of the fluid containing cavity that is separated from the second electrode by a second portion of the fluid containing cavity, the first portion being wider than the second portion of the fluid containing cavity.

7. The method of claim 6, wherein the first edge is curved to provide substantially uniform electrical resistance between substantially of the first edge of the first electrode and the second electrode.

8. The method of claim 1, wherein the first and second electrodes are disposed on opposing surfaces of the fluid containing cavity, the relevant surface of the first electrode being disposed in substantially directly facing opposition to the relevant surface of the second electrode.

9. The method of claim 8, wherein the relevant surface area of the first electrode and the relevant surface area of the second electrode are between 2 and 100 μm apart along a path of current flow.

10. The method of claim 9, wherein the relevant surface area of the first electrode and the relevant surface area of the second electrode are between 10 and 50 μm apart along the path of current flow.

11. The method of claim 9, wherein the relevant surface area of the first electrode and the relevant surface area of the second electrode are between 10 and 25 μm apart along the path of current flow.

12. A method for applying electrical current through a fluid filled cavity, comprising:
providing a first fluid filled cavity;
contacting at least first and second electrodes with the fluid in the fluid containing cavity, the first electrode having a first relevant surface area in contact with the fluid at a first electrode/fluid interface, and the second electrode having a second relevant surface area that is in contact with the fluid at a second electrode/fluid interface;
applying an alternating current to the fluid in the fluid containing cavity through the first and second electrodes, at a first frequency; and
wherein the first frequency and the relevant surface area is selected to provide less than 1V of voltage drop across at least one of the first and second electrode/fluid interfaces.

13. A method for applying electrical current through a fluid containing cavity, comprising:
providing a fluid containing cavity;
placing first, second and third electrodes in electrical contact with a fluid in the fluid containing cavity at first, second and third different points, respectively, the second point being disposed between the first point and the third point; and
simultaneously applying a first current between the first electrode and the second electrode and applying a second current between the second electrode and the third electrode.

14. The method of claim 13, wherein voltages applied at each of the first, second and thirds electrodes is maintained below 1000V.

15. The method of claim 13, wherein resistance between the first and second electrodes and between the second and third electrodes is maintained below 100 ohms.

16. The method of claim 13, wherein resistance between the first and second electrodes and between the second and third electrodes is maintained below 75 ohms.

17. The method of claim 13, wherein the first and second electrodes and second and third electrodes are between about 5 μm and 20 mm apart along a path of current flow within the fluid containing cavity.

18. The method of claim 17, wherein the first and second electrodes and second and third electrodes are less than 10 mm apart along a path of current flow within the fluid containing cavity.

19. The method of claim 17, wherein the first and second electrodes and second and third electrodes are less than 5 mm apart along a path of current flow within the fluid containing cavity.

20. The method of claim 13, wherein the first and second currents comprise alternating current.

21. The method of claim 13, wherein at least one of the first, second and third electrodes are in electrical contact with the fluid containing cavity via a fluid filled channel that is in fluid communication with the fluid filled cavity, the at least one of the first, second and third electrodes being disposed in contact with fluid in the fluid filled channel.

22. A system for applying electrical current through a fluid, comprising:
a first fluid filled cavity;
first and second electrodes disposed in electrical contact with a fluid in the fluid filled cavity, the first and second electrodes each having a relevant surface area;
an alternating current source operably coupled to the first and second electrodes and set to provide alternating current between the relevant surface areas of the first and second electrodes through the fluid at a first frequency that avoids generation of gas bubbles in the fluid at either of the first or second electrodes.

23. The system of claim 22, wherein the alternating current source is set to provide an alternating current at a frequency of greater than 1 KHz.

24. The system of claim 22, wherein the alternating current source is set to provide an alternating current at a frequency of greater than 5 KHz.

25. The system of claim 22, wherein the alternating current source is set to provide an alternating current at a frequency of greater than 10 KHz.

26. A system for applying electrical current through a fluid, comprising:
a first fluid filled cavity;
first, second and third electrodes disposed in electrical contact with fluid in the fluid containing cavity at first, second and third locations along the first fluid filled cavity, respectively, the second electrode being positioned at a location between the first and third electrodes; and
a current source operably coupled to the first, second and third electrodes and set to simultaneously supply a first current between the first and second electrodes and a second current between the second and third electrodes.

27. The system of claim 26, wherein the first, second and third locations are between about 5 μm and 20 mm apart.

28. The system of claim 27, wherein the first, second and third locations are less than 10 mm apart.

29. The system of claim 27, wherein the first, second and third locations are less than 5 mm apart.

30. The system of claim 26, wherein an electrical resistance between the first and second electrodes along a path of current flow and between the second and third electrodes along a path of current flow is less than 100 ohms.

31. The system of claim 26, wherein an electrical resistance between the first and second electrodes along a path of current flow and between the second and third electrodes along a path of current flow is less than 75 ohms.

32. The system of claim 26, wherein the current source applies voltages at each of the first, second and third electrodes that are less than 1000V.
